(19) United States
(12) Patent Application Publication
(10) Pub. No.: US 2025/0361595 A1
(43) Pub. Date: Nov. 27, 2025

(54) DEPOSITION MASK AND METHOD OF MANUFACTURING THE SAME

(71) Applicant: Samsung Display Co., LTD, Yongin-si (KR)

(72) Inventors: Jeong Kuk KIM, Yongin-si (KR); Ji Hyun JUNG, Yongin-si (KR); Jun Ho JO, Yongin-si (KR)

(73) Assignee: Samsung Display Co., LTD., Yongin-si (KR)

(21) Appl. No.: 19/005,269

(22) Filed: Dec. 30, 2024

(30) Foreign Application Priority Data
May 21, 2024 (KR) 10-2024-0065545

(51) Int. Cl. C23C 14/04; H10K 71/16

(52) U.S. Cl. CPC C23C 14/042; H10K 71/166

(57) ABSTRACT

A deposition mask includes a membrane comprising a cell region disposed on a cell opening of a substrate, and a plurality of warpage control patterns disposed along an edge portion of the cell region between the substrate and the membrane and supporting the edge portion of the cell region in a cantilever shape to control warpage of the cell region.

### CROSS-REFERENCE TO RELATED APPLICATION

This application claims priority to and benefits of Korean Patent Application No. 10-2024-0065545 under 35 U.S.C. § 119, filed on May 21, 2024, in the Korean Intellectual Property Office, the entire contents of which are incorporated herein by reference.

### BACKGROUND

### 1. Technical Field

The disclosure relates to a deposition mask, a method of manufacturing the same, and an electronic device manufactured by using the same.

### 2. Description of the Related Art

The importance of wearable devices in which a focus is formed at a distance close to user's eyes has been emphasized because of the increasing developments of information technology. The wearable devices may be in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user.

It is desirable to have a display specification of approximately 3,000 PPI (pixels per inch) or higher in the wearable devices such as the HMD device or the AR glasses to remove symptoms of dizziness a long time use. Thus, users of high-resolution small-sized organic light-emitting display devices of organic light-emitting diode on silicon (OLEDoS) technology have been increasing and becoming more popular. The OLEDoS is a technology in which organic light-emitting diodes (OLEDs) are disposed on a semiconductor wafer substrate on which complementary metal oxide semiconductor (CMOS) elements are disposed.

A display panel with a high resolution of about 3,000 PPI or higher may be manufactured using a high-resolution deposition mask. However, after manufacturing the deposition mask, warpage may occur.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a deposition mask capable of controlling warpage.

Embodiments also provide a method of manufacturing the same, and an electronic device manufactured by using the same.

However, embodiments of the disclosure are not limited to those set forth herein. The above and other embodiments of the disclosure will become more apparent to one of ordinary skill in the art to which the disclosure pertains by referencing the detailed description of the disclosure given below.

According to one or more embodiments of the disclosure, a deposition mask may include a membrane comprising a cell region disposed on a cell opening of a substrate, and a plurality of warpage control patterns disposed along an edge portion of the cell region between the substrate and the membrane and supporting the edge portion of the cell region in a cantilever shape to control warpage of the cell region.

The plurality of warpage control patterns may include a metal material.

The plurality of warpage control patterns may include first warpage control patterns and at least one second warpage control pattern having a shape different from that of the first warpage control patterns.

The at least one second warpage control pattern may include a first pattern portion including the metal material and a second pattern portion formed by melting and solidifying the metal material.

The cell region may include a pattern region through which a plurality of pixel openings are formed and a peripheral region adjacent to the pattern region, and the plurality of warpage control patterns may be disposed along the peripheral region.

Each of the plurality of warpage control patterns may extend across the peripheral region to protrude to an inside and an outside of the peripheral region.

The peripheral region may include a first peripheral region extending in a first direction and a second peripheral region extending in a second direction intersecting the first direction. The plurality of warpage control patterns may include first warpage control patterns disposed along the first peripheral region and extending in the second direction and second warpage control patterns disposed along the second peripheral region and extending in the first direction. A first warpage control pattern of the first warpage control patterns may extend toward a second warpage control pattern of the second warpage control patterns, which is adjacent to the first warpage control pattern.

The cell opening may penetrate the substrate, the cell region may be exposed through the cell opening, and each of the plurality of warpage control patterns may be partially exposed through the cell opening.

The deposition mask may further include an inorganic film disposed on the substrate. The plurality of warpage control patterns may be disposed on the inorganic film, and the membrane may be disposed on the plurality of warpage control patterns and the inorganic film.

The deposition mask may further include an inorganic film disposed on the substrate. The plurality of warpage control patterns may be disposed on the substrate. The membrane may be disposed on the plurality of warpage control patterns and the inorganic film, and the warpage control patterns and the inorganic film may have a same thickness.

According to one or more embodiments of the disclosure, a deposition mask may include a membrane comprising a cell region disposed on a cell opening of the substrate, and a reinforcement pattern disposed between the substrate and the membrane, extending along an edge portion of the cell region and supporting the edge portion of the cell region to reduce warpage of the cell region.

The cell region may include a pattern region through which a plurality of pixel openings are formed and a peripheral region adjacent to the pattern region, and the reinforcement pattern may have a ring shape extending along the peripheral region.

The cell opening may penetrate the substrate, and the reinforcement pattern may include an inner ring region exposed through the cell opening and an outer ring region disposed between the substrate and the membrane. The peripheral region may be disposed on the inner ring region of the reinforcement pattern.

The deposition mask may further include a plurality of warpage control patterns extending from the reinforcement pattern toward the pattern region.

The reinforcement pattern and the plurality of warpage control patterns may include a metal material.

The plurality of warpage control patterns may include first warpage control patterns including the metal material and second warpage control patterns formed by melting and solidifying the metal material.

The deposition mask may further include an inorganic film disposed on the substrate. The reinforcement pattern may be disposed on the inorganic film, and the membrane may be disposed on the reinforcement pattern and the inorganic film.

The deposition mask may further include an inorganic film disposed on the substrate, and the reinforcement pattern may be disposed on the substrate. The membrane may be disposed on the reinforcement pattern and the inorganic film, and the reinforcement pattern and the inorganic film may have a same thickness.

According to one or more embodiments of the disclosure, a deposition mask may include a membrane comprising a cell region disposed on a cell opening of a substrate, and a plurality of warpage control patterns disposed along an edge portion of the cell region between the substrate and the membrane and supporting the edge portion of the cell region using a bending moment to control warpage of the cell region.

According to one or more embodiments of the disclosure, a method of manufacturing a deposition mask may include forming a plurality of warpage control patterns on a substrate, forming a membrane comprising a cell region on the plurality of warpage control patterns, forming a cell opening exposing the cell region by partially etching the substrate, measuring warpage of the cell region, and controlling the warpage of the cell region based on a result of the measuring of the warpage of the cell region. The plurality of warpage control patterns may be disposed along an edge portion of the cell region, and the warpage of the cell region may be controlled by melting and solidifying at least one of the plurality of warpage control patterns.

The method may further include forming a reinforcement pattern having a ring shape on the substrate. The plurality of warpage control patterns may extend inward from the reinforcement pattern and may be formed simultaneously with the reinforcement pattern.

According to one or more embodiments of the disclosure, an electronic device may include a display substrate, and light-emitting layers formed on the display substrate by using a deposition mask. The deposition mask may include a membrane comprising a cell region disposed on a cell opening of a mask substrate, and a plurality of warpage control patterns disposed along an edge portion of the cell region between the mask substrate and the membrane and supporting the edge portion of the cell region in a cantilever shape to control warpage of the cell region.

According to the embodiments, warpage control patterns may be disposed between the membrane and the substrate, and warpage of a cell region may be readily controlled by the warpage control patterns.

Other features and embodiments may be apparent from the following detailed description and the drawings.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1 is a schematic exploded perspective view illustrating a display device;

FIG. 2 is a schematic block diagram for explaining the display device shown in FIG. 1;

FIG. 3 is a schematic diagram of an equivalent circuit for explaining an example of a first sub-pixel shown in FIG. 2;

FIG. 4 is a schematic plan view illustrating an example of the display panel shown in FIG. 1;

FIG. 5 is a schematic plan view illustrating an example of the display area shown in FIG. 4;

FIG. 6 is a schematic plan view illustrating an example of the display area shown in FIG. 4;

FIG. 7 is a schematic cross-sectional view illustrating an example of the display panel taken along line I-I′ of FIG. 5;

FIG. 8 is a schematic perspective view illustrating an example of a head mounted display;

FIG. 9 is a schematic exploded perspective view illustrating the head mounted display shown in FIG. 8;

FIG. 10 is a schematic perspective view illustrating an example of a head mounted display;

FIG. 11 is a schematic plan view illustrating a deposition mask according to an embodiment of the disclosure;

FIG. 12 is a schematic cross-sectional view taken along line II-II′ shown in FIG. 11;

FIG. 13 is a schematic cross-sectional view taken along line III-III′ shown in FIG. 11;

FIG. 14 is a schematic bottom view illustrating the cell region shown in FIG. 11;

FIG. 15 is a schematic bottom view illustrating a deposition mask according to an embodiment of the disclosure;

FIG. 16 is a schematic bottom view illustrating a deposition mask according to an embodiment of the disclosure;

FIG. 17 is a schematic enlarged bottom view illustrating the first warpage control pattern and the second warpage control pattern shown in FIG. 16;

FIG. 18 is a schematic cross-sectional view illustrating a deposition mask according to an embodiment of the disclosure;

FIG. 19 is a schematic plan view illustrating a deposition mask according to an embodiment of the disclosure;

FIG. 20 is a schematic cross-sectional view taken along line IV-IV′ shown in FIG. 19;

FIG. 21 is a schematic plan view illustrating a deposition mask according to an embodiment of the disclosure;

FIG. 22 is a schematic cross-sectional view taken along line V-V′ shown in FIG. 21;

FIG. 23 is a schematic cross-sectional view taken along line VI-VI′ shown in FIG. 21;

FIG. 24 is a schematic bottom view illustrating a deposition mask according to an embodiment of the disclosure;

FIG. 25 is a schematic enlarged bottom view illustrating the first warpage control pattern and the second warpage control pattern shown in FIG. 24;

FIG. 26 is a schematic cross-sectional view illustrating a deposition mask according to an embodiment of the disclosure; and

FIGS. 27 to 32 are schematic cross-sectional views illustrating a method of manufacturing a deposition mask according to an embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the disclosure. Some of the parts which are not associated with the description may not be provided in order to describe embodiments of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

Spatially relative terms, such as “below,” “beneath,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawing is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Although the terms “first,” “second,” “third,” or the like may be used herein to describe various elements, these elements should not be limited by these terms. These terms are used to distinguish one element from another element or for the convenience of description and explanation thereof. For example, when “a first element” is discussed below could be termed “a second element” or “a third element,” and “a second element” and “a third element” may be termed in a similar manner without departing from the teachings of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, ±20%, ±10%, ±5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Unless otherwise defined or implied, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly defined herein.

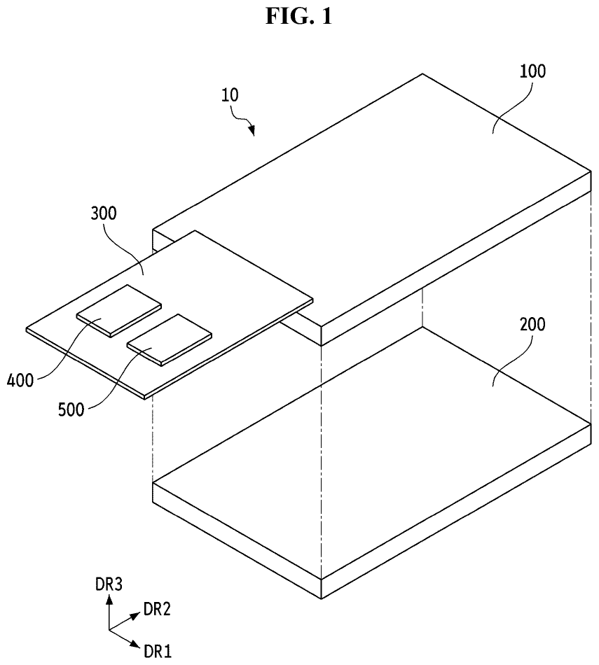

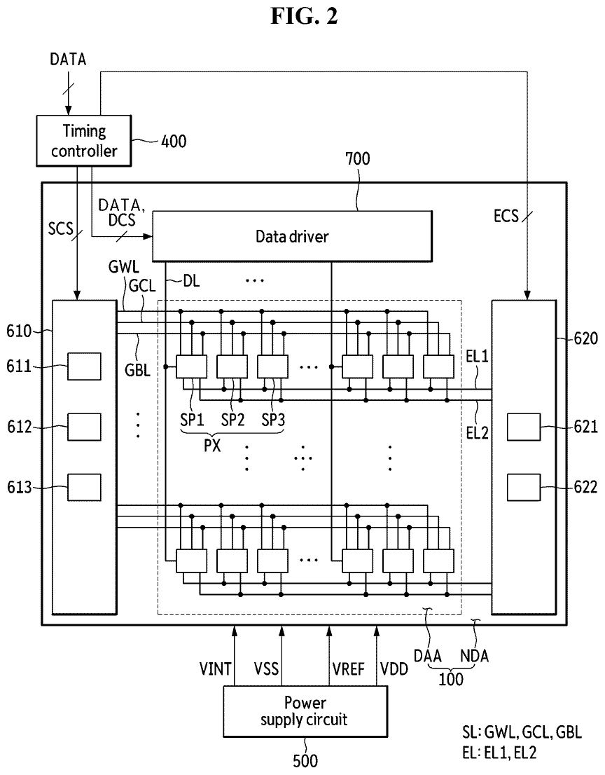

FIG. 1 is a schematic exploded perspective view illustrating a display device. FIG. 2 is a schematic block diagram for explaining the display device shown in FIG. 1.

Referring to FIGS. 1 and 2, a display device 10 may be a device displaying a moving image or a still image. The display device 10 may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC), and the like. For example, the display device 10 may be applied as a display device of electronic devices such as a television, a laptop, a monitor, a billboard, an Internet-of-Things (IoT) device, and the like. In other embodiments, the display device 10 may be applied to electronic devices such as a smart watch, a watch phone, a head mounted display (HMD) for implementing virtual reality and augmented reality, and the like.

The display device 10 may include a display panel 100, a heat dissipation layer 200, a circuit board 300, a timing controller (or a timing control circuit) 400, and a power supply circuit 500.

The display panel 100 may have a planar shape similar to a polygonal shape such as a quadrilateral shape. For example, the display panel 100 may have a planar shape similar to a quadrilateral shape, having a short side of a first direction DR1 and a long side of a second direction DR2 intersecting (e.g., crossing) the first direction DR1. In the display panel 100, a corner where a short side in the first direction DR1 and a long side in the second direction DR2 meet may be right-angled or rounded with a curvature (e.g., a predetermined or selectable curvature). The planar shape of the display panel 100 is not limited to a quadrilateral shape, and may have other shapes such as another polygonal shape, a circular shape, or an elliptical shape. The planar shape of the display device 10 may be the above-described planar shape, but the disclosure is not limited thereto.

The display panel 100 may include pixels PX, scan lines SL, emission control lines EL, data lines DL, a scan driver 610, an emission driver 620, and a data driver 700. As shown in FIG. 2, the display panel 100 may be divided into a display area DAA displaying an image and a non-display area NDA not displaying an image.

The pixels PX may be disposed in the display area DAA. The pixels PX may be disposed (e.g., arranged) in a matrix form along the first direction DR1 and the second direction DR2. The scan lines SL and the emission control lines EL may extend in the first direction DR1 and be arranged in the second direction DR2. The data lines DL may extend in the second direction DR2 and be arranged in the first direction DR1.

The scan lines SL may include write scan lines GWL, control scan lines GCL, and bias scan lines GBL. The emission control lines EL may include first emission control lines EL1 and second emission control lines EL2.

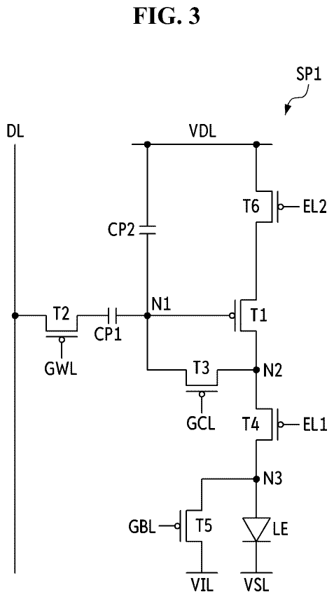

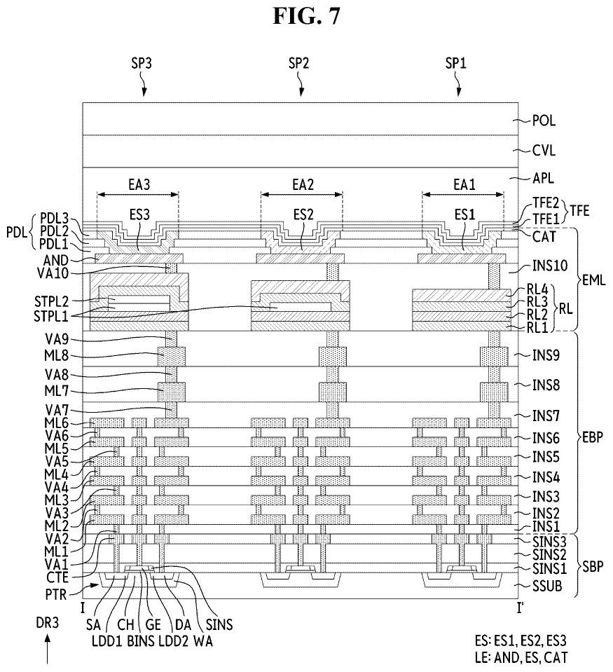

The pixels PX may include sub-pixels SP1, SP2, and SP3. The sub-pixels SP1, SP2, and SP3 may include pixel transistors T1, T2, T3, T4, and T5 (e.g., refer to FIG. 3). The pixel transistors may be formed by a semiconductor process, and may be disposed on a semiconductor substrate SSUB (e.g., refer to FIG. 7). For example, the pixel transistors of the data driver 700 may be formed through a complementary metal oxide semiconductor (CMOS) process, but the disclosure is not limited thereto.

Each of the sub-pixels SP1, SP2, and SP3 may be electrically connected to a write scan line GWL among the write scan lines GWL, a control scan line GCL among the control scan lines GCL, a bias scan line GBL among the bias scan lines GBL, a first emission control line EL1 among the first emission control lines EL1, a second emission control line EL2 among the second emission control lines EL2, and a data line DL among the data lines DL. Each of the sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include scan transistors, and the emission driver 620 may include light-emitting transistors. The scan transistors and the light-emitting transistors may be formed on the semiconductor substrate SSUB (e.g., refer to FIG. 7) through a semiconductor process. For example, the scan transistors and the light-emitting transistors may be formed through a CMOS process, but the embodiment of the specification is not limited thereto.

The scan driver 610 may include a write scan signal output part 611, a control scan signal output part 612, and a bias scan signal output part 613. Each of the write scan signal output part 611, the control scan signal output part 612, and the bias scan signal output part 613 may receive a scan timing control signal SCS from the timing controller (or the timing control circuit) 400. The write scan signal output part 611 may generate write scan signals according to the scan timing control signal SCS of the timing controller (or the timing control circuit) 400 and output the write scan signals sequentially to the write scan lines GWL. The control scan signal output part 612 may generate control scan signals in response to the scan timing control signal SCS and sequentially output the control scan signals to the control scan lines GCL. The bias scan signal output part 613 may generate bias scan signals according to the scan timing control signal SCS and output the bias scan signals sequentially to bias scan lines GBL.

The emission driver 620 may include a first emission control driver 621 and a second emission control driver 622. Each of the first emission control driver 621 and the second emission control driver 622 may receive an emission timing control signal ECS from the timing controller (or the timing control circuit) 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include data transistors. The data transistors may be formed through a semiconductor process, and formed on the semiconductor substrate SSUB (e.g., refer to FIG. 7). For example, the data transistors may be formed through a CMOS process, but the disclosure is not limited thereto.

The data driver 700 may receive digital video data DATA and a data timing control signal DCS from the timing controller (or the timing control circuit) 400. The data driver 700 may convert the digital video data DATA into analog data voltages according to the data timing control signal DCS and output the analog data voltages to the data lines DL. The sub-pixels SP1, SP2, and SP3 may be selected by the write scan signal of the scan driver 610, and the data voltages (e.g., the analog data voltages) may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on a surface of the display panel 100, for example, on a rear surface of the display panel 100. The heat dissipation layer 200 may dissipate heat generated from the display panel 100. The heat dissipation layer 200 may include a metal layer having high thermal conductivity. For example, the heat dissipation layer 200 may include at least one of graphite, silver (Ag), copper (Cu), and aluminum (Al). However, the disclosure is not limited thereto.

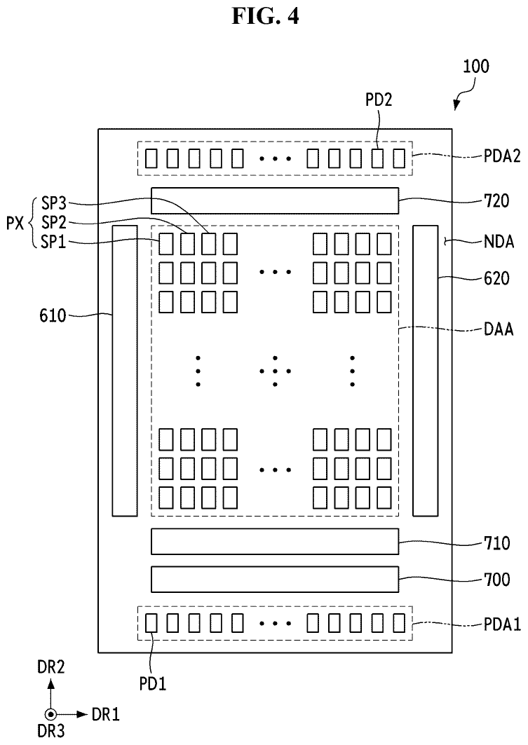

The circuit board 300 may be electrically connected to first pads PD1 (e.g., refer to FIG. 4) of a first pad portion PDA1 (e.g., refer to FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent or folded. An end of the circuit board 300 may be disposed on the rear surface of the display panel 100 and/or the rear surface of the heat dissipation layer 200. Another end of the circuit board 300 may be electrically connected to the first pads PD1 (e.g., refer to FIG. 4) of the first pad portion PDA1 (e.g., refer to FIG. 4) of the display panel 100 by using a conductive adhesive member. An end of the circuit board 300 may be an opposite end of the another end of the circuit board 300.

The timing controller (or the timing control circuit) 400 may receive digital video data and timing signals provided (e.g., inputted) from the outside. The timing controller (or the timing control circuit) 400 may generate the scan timing control signal SCS, the emission timing control signal ECS, and the data timing control signal DCS for controlling the display panel 100 in response to the timing signals. The timing controller (or the timing control circuit) 400 may output the scan timing control signal SCS to the scan driver 610, and output the emission timing control signal ECS to the emission driver 620. The timing controller (or the timing control circuit) 400 may output the digital video data and the data timing control signal DCS to the data driver 700.

The power supply circuit 500 may generate panel driving voltages according to a power voltage from the outside. For example, the power supply circuit 500 may generate a first driving voltage VSS, a second driving voltage VDD, and a third driving voltage VINT and supply the first driving voltage VSS, the second driving voltage VDD, and the third driving voltage VINT to the display panel 100. Detailed description of the first driving voltage VSS, the second driving voltage VDD, and the third driving voltage VINT is provided below in conjunction with FIG. 3.

Each of the timing controller (or the timing control circuit) 400 and the power supply circuit 500 may be formed as an integrated circuit (IC) and attached to a surface of the circuit board 300. The scan timing control signal SCS, the emission timing control signal ECS, digital video data DATA, and the data timing control signal DCS of the timing controller (or the timing control circuit) 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

For example, the timing controller (or the timing control circuit) 400, the power supply circuit 500, the scan driver 610, the emission driver 620, and the data driver 700 may be disposed in the non-display area NDA of the display panel 100. The timing controller (or the timing control circuit) 400 may include timing transistors, and each power supply circuit 500 may include power transistors. The timing transistors and the power transistors may be formed through a semiconductor process, and formed on the semiconductor substrate SSUB (e.g., refer to FIG. 7). For example, the timing transistors and the power transistors may be formed through a CMOS process, but the disclosure is not limited thereto. Each of the timing controller (or the timing control circuit) 400 and the power supply circuit 500 may be disposed between the data driver 700 and the first pad portion PDA1 (e.g., refer to FIG. 4).

FIG. 3 is a schematic diagram of an equivalent circuit for explaining an example of a first sub-pixel shown in FIG. 2.

Referring to FIG. 3, the first sub-pixel SP1 may be electrically connected to the write scan line GWL, the control scan line GCL, the bias scan line GBL, the first emission control line EL1, the second emission control line EL2, and the data line DL. The first sub-pixel SP1 may be electrically connected to a first driving voltage line VSL to which the first driving voltage VSS (e.g., refer to FIG. 2) corresponding to a low potential voltage is applied, a second driving voltage line VDL to which the second driving voltage VDD (e.g., refer to FIG. 2) corresponding to a high potential voltage is applied, and a third driving voltage line VIL to which the third driving voltage VINT (e.g., refer to FIG. 2) corresponding to an initialization voltage is applied. For example, the first driving voltage line VSL may be a low potential voltage line, the second driving voltage line VDL may be a high potential voltage line, and the third driving voltage line VIL may be an initialization voltage line. The first driving voltage VSS may be lower than the third driving voltage VINT. The second driving voltage VDD may be higher than the third driving voltage VINT.

The first sub-pixel SP1 may include transistors T1 to T6 (e.g., a first transistor T1, a second transistor T2, a third transistor T3, a fourth transistor T4, a fifth transistor T5, and a sixth transistor T6), a light-emitting element LE, a first capacitor CP1, and a second capacitor CP2.

The light-emitting element LE may emit light in response to a driving current flowing through the channel of the first transistor T1. The emission amount of the light-emitting element LE may be proportional to the driving current. The light-emitting element LE may be disposed between a fourth transistor T4 and the first driving voltage line VSL. A first electrode of the light-emitting element LE may be electrically connected to a drain electrode of the fourth transistor T4, and a second electrode of the light-emitting element LE may be electrically connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. For example, the light-emitting element LE may be an inorganic light-emitting element including a first electrode, a second electrode, and an inorganic semiconductor disposed between the first electrode and the second electrode. For example, in case that the light-emitting element LE is the inorganic light-emitting element, the light-emitting element LE may be a micro light-emitting diode.

The first transistor T1 may be a driving transistor that controls a source-drain current (hereinafter referred to as “driving current”) flowing between a source electrode and a drain electrode of the first transistor T1 according to a voltage applied to a gate electrode of the first transistor T1. The gate electrode of the first transistor T1 may be electrically connected to a first node N1, the source electrode of the first transistor T1 may be electrically connected to a drain electrode of a sixth transistor T6, and the drain electrode of the first transistor T1 may be electrically connected to a second node N2.

The second transistor T2 may be disposed between an electrode of the first capacitor CP1 and the data line DL. The second transistor T2 may be turned on by the write scan signal of the write scan line GWL to electrically connect the electrode of the first capacitor CP1 to the data line DL. Accordingly, the data voltage of the data line DL may be applied to the electrode of the first capacitor CP1. The second transistor T2 may include a gate electrode electrically connected to the write scan line GWL, a source electrode electrically connected to the data line DL, and a drain electrode electrically connected to the electrode of the first capacitor CP1.

The third transistor T3 may be disposed between the first node N1 and the second node N2. The third transistor T3 may be turned on by the control scan signal of the control scan line GCL to electrically connect the first node N1 to the second node N2. Thus, in case that the gate electrode and the source electrode of the first transistor T1 are electrically connected to each other, the first transistor T1 may operate like a diode. The third transistor T3 may include a gate electrode electrically connected to the control scan line GCL, a source electrode electrically connected to the second node N2, and a drain electrode electrically connected to the first node N1.

The fourth transistor T4 may be electrically connected between the second node N2 and a third node N3. The fourth transistor T4 may be turned on by the first emission control signal of the first emission control line EL1 to electrically connect the second node N2 to the third node N3. Accordingly, the driving current of the first transistor T1 may be supplied to the light-emitting element LE. The fourth transistor T4 may include a gate electrode electrically connected to the first emission control line EL1, a source electrode electrically connected to the second node N2, and a drain electrode electrically connected to the third node N3.

The fifth transistor T5 may be disposed between the third node N3 and the third driving voltage line VIL. The fifth transistor T5 may be turned on by the bias scan signal of the bias scan line GBL to electrically connect the third node N3 to the third driving voltage line VIL. Accordingly, the third driving voltage VINT of the third driving voltage line VIL may be applied to the first electrode of the light-emitting element LE. The fifth transistor T5 may include a gate electrode electrically connected to the bias scan line GBL, a source electrode electrically connected to the third node N3, and a drain electrode electrically connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to electrically connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode electrically connected to the second emission control line EL2, a source electrode electrically connected to the second driving voltage line VDL, and the drain electrode electrically connected to the source electrode of the first transistor T1.

The first capacitor CP1 may be disposed between the first node N1 and the drain electrode of the second transistor T2. The first capacitor CP1 may include an electrode electrically connected to the drain electrode of the second transistor T2 and another electrode electrically connected to the first node N1.

The second capacitor CP2 may be formed between the gate electrode of the first transistor T1 and the second driving voltage line VDL. The second capacitor CP2 may include an electrode electrically connected to the gate electrode of the first transistor T1 and the another electrode electrically connected to the second driving voltage line VDL.

The first node N1 may be a junction between the gate electrode of the first transistor T1, the drain electrode of the third transistor T3, the another electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the disclosure is not limited thereto. Each of the first to sixth transistors T1 to T6 may be an N-type MOSFET. In other embodiments, some of the first to sixth transistors T1 to T6 may be P-type MOSFETs, and each of the remaining transistors may be an N-type MOSFET.

In FIG. 3, the first sub-pixel SP1 may include six transistors T1 to T6 and two capacitors C1 and C2. However, the disclosure is not limited thereto, and the equivalent circuit of the first sub-pixel SP1 may not be limited to that shown in FIG. 3. For example, the number of transistors and the number of capacitors of the first sub-pixel SP1 are not limited to those shown in FIG. 3.

The equivalent circuit of the second sub-pixel SP2 and the equivalent circuit of the third sub-pixel SP3 may be substantially the same as the equivalent circuit of the first sub-pixel SP1 described in conjunction with FIG. 3. Therefore, detailed description of the same or similar constituent elements of the second sub-pixel SP2 and the third sub-pixel SP3 is omitted in the disclosure.

FIG. 4 is a schematic plan view illustrating an example of the display panel shown in FIG. 1.

Referring to FIG. 4, the display area DAA of the display panel 100 may include the pixels PX disposed (e.g., arranged) in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on a first side of the display area DAA, and the emission driver 620 may be disposed on a second side of the display area DAA. For example, the scan driver 610 may be disposed on a side of the display area DAA in the first direction DR1, and the emission driver 620 may be disposed on another side of the display area DAA in the first direction DR1. For example, as shown in FIG. 4, the scan driver 610 may be disposed on a left side of the display area DAA, and the emission driver 620 may be disposed on a right side of the display area DAA. However, the disclosure is not limited thereto, and the scan driver 610 and the emission driver 620 may be disposed on both the first side and the second side of the display area DAA. For example, the scan driver 610 and the emission driver 620 may be disposed on the first side or the display area DAA. In other embodiment, the scan driver 610 and the emission driver 620 may be disposed on the second side of the display area DAA.

The first pad portion PDA1 may include the first pads PD1 electrically connected to pads or bumps of the circuit board 300 through a conductive adhesive member. The first pad portion PDA1 may be disposed on a third side of the display area DAA. For example, the first pad portion PDA1 may be disposed on a side of the display area DAA in the second direction DR2. The first pad portion PDA1 may be disposed outside the data driver 700 in the second direction DR2. For example, as shown in FIG. 4, the first pad portion PDA1 may be disposed adjacent to (e.g., be close to) an edge of the display panel 100 than the data driver 700.

The second pad portion PDA2 may include second pads PD2 corresponding to inspection pads that test whether the display panel 100 operates normally. The second pads PD2 may be electrically connected to a jig or probe pins during an inspection process, or may be electrically connected to a circuit board for inspection. The circuit board for inspection may be a printed circuit board including (or made of) a rigid material or a flexible printed circuit board including (or made of) a flexible material.

The second pad portion PDA2 may be disposed on a fourth side of the display area DAA. For example, the second pad portion PDA2 may be disposed on the another side of the display area DAA in the second direction DR2. The second pad portion PDA2 may be disposed outside the second distribution circuit 720 in the second direction DR2. For example, as shown in FIG. 4, the second pad portion PDA2 may be disposed adjacent to (e.g., be close to) the edge of the display panel 100 than the second distribution circuit 720.

The first distribution circuit 710 may distribute data voltages applied through the first pad portion PDA1 to the data lines DL. For example, the first distribution circuit 710 may distribute the data voltages applied through a first pad PD1 of the first pad portion PDA1 to the P-th data lines DL (P is a positive integer of 2 or greater). Thus, the number of the first pads PD1 may be reduced. The first distribution circuit 710 may be disposed on the third side of the display area DAA of the display panel 100. For example, the first distribution circuit 710 may be disposed on a side of the display area DAA in the second direction DR2. For example, as shown in FIG. 4, the first distribution circuit 710 may be disposed on a lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may inspect the operation of the pixels PX (or each of the pixels PX) in the display area DAA. The second distribution circuit 720 may be disposed on the fourth side of the display area DAA of the display panel 100. For example, the second distribution circuit 720 may be disposed on the another side of the display area DAA in the second direction DR2. For example, as shown in FIG. 4, the second distribution circuit 720 may be disposed on an upper side of the display area DAA.

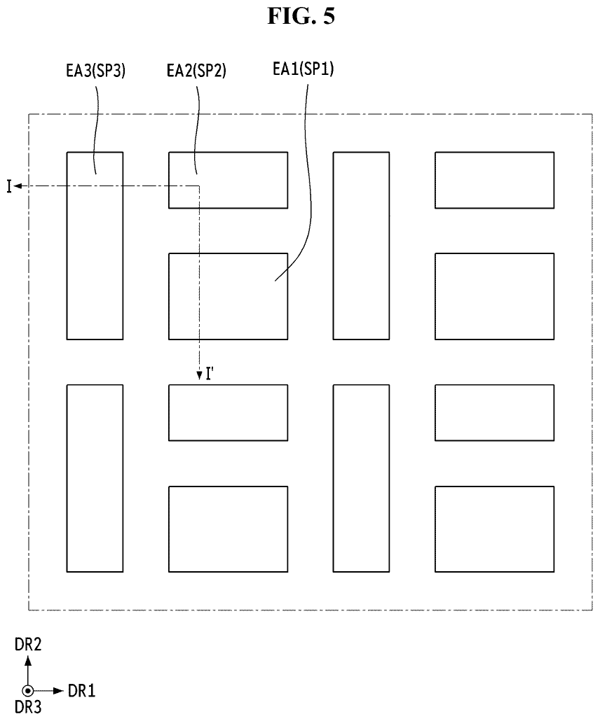

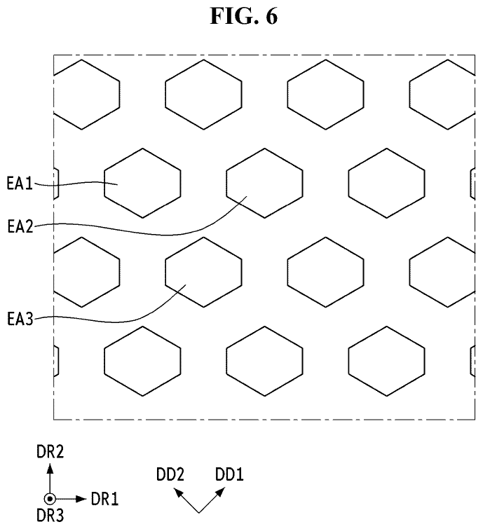

FIG. 5 is a schematic plan view illustrating an example of the display area shown in FIG. 4. FIG. 6 is a schematic plan view illustrating an example of the display area shown in FIG. 4.

Referring to FIG. 5, each of the pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (e.g., refer to FIG. 7). For example, each of the first emission area EA1, the second emission area EA2, and the third emission area EA3 may be an area defined by a first pixel defining film PDL1 (e.g., refer to FIG. 7).

The length of the third emission area EA3 in the first direction DR1 may be less than the length of the first emission area EA1 in the first direction DR1, and may be less than the length of the second emission area EA2 in the first direction DR1. The first emission area EA1 and the second emission area EA2 may have a same length (or substantially the same length) in the first direction DR1.

The length of the third emission area EA3 in the second direction DR2 may be greater than the length of the first emission area EA1 in the second direction DR2, and may be greater than the length of the second emission area EA2 in the second direction DR2. The length of the first emission area EA1 in the second direction DR2 may be greater than the length of the second emission area EA2 in the second direction DR2.

In each of the pixels PX, the first emission area EA1 and the second emission area EA2 may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. For example, the area of the first emission area EA1, the area of the second emission area EA2, and the area of the third emission area EA3 may be different from each other. However, the disclosure is not limited thereto.

The first emission area EA1 may emit light of a first color, the second emission area EA2 may emit light of a second color, and the third emission area EA3 may emit light of a third color. For example, the light of the first color may be light of a red wavelength band, the light of the second color may be light of a green wavelength band, and the light of the third color may be light of a blue wavelength band. For example, the blue wavelength band may be a wavelength band of light whose main peak wavelength is in a range of about 370 nm to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

For example, as shown in FIG. 6, the first emission area EA1, the second emission area EA2, and the third emission area EA3 may be disposed in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

In FIGS. 5 and 6, each of the pixels PX may include the three emission areas EA1, EA2, and EA3. However, the disclosure is not limited thereto. For example, each of the pixels PX may include four emission areas. For example, each of the emission areas EA1, EA2, and EA3 may have a polygonal, circular, elliptical, or atypical shape in a plan view, unlike those shown in FIGS. 5 and 6.

The arrangement of the emission areas EA1, EA2, and EA3 of the pixels PX is not limited to that illustrated in FIGS. 5 and 6. For example, the emission areas of the pixels PX may be disposed in a stripe structure in which the emission areas are disposed (e.g., arranged) in the first direction DR1, a PenTile® structure in which the emission areas are disposed (e.g., arranged) in a diamond shape, or the like.

FIG. 7 is a schematic cross-sectional view illustrating an example of the display panel taken along line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP may include the semiconductor substrate SSUB including pixel transistors PTR, semiconductor insulating films covering the pixel transistors PTR, and contact terminals CTE electrically connected to the pixel transistors PTR, respectively. The pixel transistors PTR may be the first to sixth transistors T1 to T6 described with reference to FIG. 3.

The semiconductor substrate SSUB may be a silicon substrate, a germanium substrate, a silicon-germanium substrate, or the like. The semiconductor substrate SSUB may be a substrate doped with a first type impurity. Well regions WA may be disposed at top surface portions of the semiconductor substrate SSUB. The well regions WA may be regions doped with a second type impurity. The second type impurity may be different from the aforementioned first type impurity. For example, in case that the first type impurity is a p-type impurity, the second type impurity may be an n-type impurity. In other embodiments, in case that the first type impurity is an n-type impurity, the second type impurity may be a p-type impurity.

Each of the well regions WA may include a source region SA corresponding to the source electrode of the pixel transistor PTR, a drain region DA corresponding to the drain electrode of the pixel transistor PTR, and a channel region CH disposed between the source region SA and the drain region DA.

A lower insulating film BINS may be disposed between a gate electrode GE and the well region WA. A side insulating film SINS may be disposed on a side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of the well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. For example, the first low-concentration impurity region LDD1 and the second low-concentration impurity region LDD2 may be disposed between the source region SA and the drain region DA, and the distance between the source region SA and the drain region DA may be increased. Thus, the length of the channel region CH of each of the pixel transistors PTR may increase. Therefore, punch-through and hot carrier phenomena that might be caused by a short channel may be reduced or prevented.

A first semiconductor insulating film SINS1 may be disposed on the semiconductor substrate SSUB. The first semiconductor insulating film SINS1 may include (e.g., be formed of) at least one inorganic material of silicon carbonitride (SiCN) and a silicon oxide (SiOx), but the disclosure is not limited thereto.

A second semiconductor insulating film SINS2 may be disposed on the first semiconductor insulating film SINS1. The second semiconductor insulating film SINS2 may include (e.g., be formed of) a silicon oxide (SiOx)-based inorganic film, but the embodiment of the specification is not limited thereto.

The contact terminals CTE may be disposed on the second semiconductor insulating film SINS2. Each of the contact terminals CTE may be electrically connected to any one of the gate electrode GE, the source region SA, and the drain region DA of each of the pixel transistors PTR through contact plugs penetrating the first semiconductor insulating film SINS1 and the second semiconductor insulating film INS2. The contact terminals CTE may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the contact terminals CTE may include an alloy including at least one of the above-described metals. However, the disclosure is not limited thereto.

A third semiconductor insulating film SINS3 may be disposed on side surfaces of the contact terminals CTE. A top surface of each of the contact terminals CTE may be exposed without being covered by the third semiconductor insulating film SINS3. The third semiconductor insulating film SINS3 may include (e.g., be formed of) a silicon oxide (SiOx)-based inorganic film, but the embodiment of the specification is not limited thereto.

The semiconductor substrate SSUB may be replaced with a glass substrate or a polymer resin substrate such as polyimide. Thin film transistors may be disposed on the glass substrate or the polymer resin substrate. The glass substrate may be a rigid substrate that does not bend, and the polymer resin substrate may be a flexible substrate that may be bent or curved.

The light-emitting element backplane EBP may include conductive layers ML1 to ML8 (e.g., a first conductive layer ML1, a second conductive layer ML2, a third conductive layer ML3, a fourth conductive layer ML4, a fifth conductive layer ML5, a sixth conductive layer ML6, a seventh conductive layer ML7, and an eighth conductive layer ML8), vias VA1 to VA9 (e.g., a first via VA1, a second via VA2, a third via VA3, a fourth via VA4, a fifth via VA5, a sixth via VA6, a seventh via VA7, an eighth via VA8, and a ninth via VA9), and insulating films INS1 to INS9 (e.g., a first insulating film INS1, a second insulating film INS2, a third insulating film INS3, a fourth insulating film INS4, a fifth insulating film INS5, a sixth insulating film INS6, a seventh insulating film INS7, an eighth insulating film INS8, and a ninth insulating film INS9). The insulating films INS1 to INS9 may be used for electrical insulation between the conductive layers ML1 to ML8.

The first to eighth conductive layers ML1 to ML8 may be electrically connected to the contact terminals CTE exposed from the semiconductor backplane SBP, and implement the circuit of the first sub-pixel SP1 shown in FIG. 3. For example, the first to sixth transistors T1 to T6 may be formed in the semiconductor backplane SBP, and the electrical connection of the first to sixth transistors T1 to T6 and the first and second capacitors C1 and C2 may be implemented by the first to eighth conductive layers ML1 to ML8. The electrical connection between the drain region corresponding to the drain electrode of the fourth transistor T4, the source region corresponding to the source electrode of the fifth transistor T5, and a first electrode AND of the light-emitting element LE (e.g., refer to FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be electrically connected to the contact terminal CTE exposed from the semiconductor backplane SBP. Each of the first conductive layers ML1 may be disposed on the first insulating film INS1 and may be electrically connected to the first via VA1.

The second insulating film INS2 may be disposed on the first insulating film INS1 and the first conductive layers ML1. Each of the second vias VA2 may penetrate the second insulating film INS2 and be electrically connected to the first conductive layer ML1. Each of the second conductive layers ML2 may be disposed on the second insulating film INS2 and may be electrically connected to the second via VA2.

The third insulating film INS3 may be disposed on the second insulating film INS2 and the second conductive layers ML2. Each of the third vias VA3 may penetrate the third insulating film INS3 and be electrically connected to the second conductive layer ML2. Each of the third conductive layers ML3 may be disposed on the third insulating film INS3 and may be electrically connected to the third via VA3.

The fourth insulating film INS4 may be disposed on the third insulating film INS3 and the third conductive layers ML3. Each of the fourth vias VA4 may penetrate the fourth insulating film INS4 and be electrically connected to the third conductive layer ML3. Each of the fourth conductive layers ML4 may be disposed on the fourth insulating film INS4 and may be electrically connected to the fourth via VA4.

The fifth insulating film INS5 may be disposed on the fourth insulating film INS4 and the fourth conductive layers ML4. Each of the fifth vias VA5 may penetrate the fifth insulating film INS5 and be electrically connected to the fourth conductive layer ML4. Each of the fifth conductive layers ML5 may be disposed on the fifth insulating film INS5 and may be electrically connected to the fifth via VA5.

The sixth insulating film INS6 may be disposed on the fifth insulating film INS5 and the fifth conductive layers ML5. Each of the sixth vias VA6 may penetrate the sixth insulating film INS6 and be electrically connected to the fifth conductive layer ML5. Each of the sixth conductive layers ML6 may be disposed on the sixth insulating film INS6 and may be electrically connected to the sixth via VA6.

The seventh insulating film INS7 may be disposed on the sixth insulating film INS6 and the sixth conductive layers ML6. Each of the seventh vias VA7 may penetrate the seventh insulating film INS7 and be electrically connected to the sixth conductive layer ML6. Each of the seventh conductive layers ML7 may be disposed on the seventh insulating film INS7 and may be electrically connected to the seventh via VA7.

The eighth insulating film INS8 may be disposed on the seventh insulating film INS7 and the seventh conductive layers ML7. Each of the eighth vias VA8 may penetrate the eighth insulating film INS8 and be electrically connected to the seventh conductive layer ML7. Each of the eighth conductive layers ML8 may be disposed on the eighth insulating film INS8 and may be electrically connected to the eighth via VA8.

The first to eighth conductive layers ML1 to ML8 may include (or be made of) a same material (or substantially the same material). The first to eighth conductive layers ML1 to ML8 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the first to eighth conductive layers ML1 to ML8 may include an alloy including at least one of the above-described metals. However, the disclosure is not limited thereto. The first to eighth vias VA1 to VA8 may include (or be made of) a same material (or substantially the same material). The first to eighth vias VA1 to VA8 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the first to eighth vias VA1 to VA8 may include an alloy including at least one of the above-described metals. However, the disclosure is not limited thereto. The first to eighth insulating films INS1 to INS8 may include (e.g., be formed of) a silicon oxide (SiOx)-based inorganic film, but the embodiment of the specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The second conductive layer ML2, the third conductive layer ML3, the fourth conductive layer ML4, the fifth conductive layer ML5, and the sixth conductive layer ML6 may have a same thickness (or substantially the same thickness). For example, the thickness of the first conductive layer ML1 may be approximately 1,360 Å. The thickness of each of the second conductive layer ML2, the third conductive layer ML3, the fourth conductive layer ML4, the fifth conductive layer ML5, and the sixth conductive layer ML6 may be approximately 1,440 Å. The thickness of each of the first via VAL, the second via VA2, the third via VA3, the fourth via VA4, the fifth via VA5, and the sixth via VA6 may be approximately 1,150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 may be greater than the thickness of the seventh via VA7, and the thickness of the eighth conductive layer ML8 may be greater than the thickness of the eighth via VA8. The thickness of each of the seventh via VA7 and the eighth via VA8 may be greater than the thickness of each of the first via VA1, the second via VA2, the third via VA3, the fourth via VA4, the fifth via VA5, and the sixth via VA6. The seventh conductive layer ML7 and the eighth conductive layer ML8 may have a same thickness (e.g., substantially the same thickness). For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

The ninth insulating film INS9 may be disposed on the eighth insulating film INS8 and the eighth conductive layer ML8. The ninth insulating film INS9 may include (e.g., be formed of) a silicon oxide (SiOx)-based inorganic film, but the embodiment of the specification is not limited thereto.

Each of the ninth vias VA9 may penetrate the ninth insulating film INS9 and be electrically connected to the eighth conductive layer ML8. The ninth vias VA9 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the ninth vias VA9 may include an alloy including at least one of the above-described metals. However, the disclosure is not limited thereto. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode (e.g., first reflective electrodes RL1, second reflective electrodes RL2, third reflective electrodes RL3, fourth reflective electrodes RL4, or the like), a first step layer STPL1, and a second step layer STPL2. For example, the reflective electrode layer RL may include the first to fourth reflective electrodes RL1, RL2, RL3, and RL4 as shown in FIG. 7.

Each of the first reflective electrodes RL1 may be disposed on the ninth insulating film INS9, and may be electrically connected to the ninth via VA9. The first reflective electrodes RL1 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the first reflective electrodes RL1 may include an alloy including at least one of the above-described metals. However, the disclosure is not limited thereto. For example, the first reflective electrodes RL1 may include titanium nitride (TiN).

Each of the second reflective electrodes RL2 may be disposed on the first reflective electrode RL1. The second reflective electrodes RL2 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the second reflective electrodes RL2 may include an alloy including at least one of the above-described metals. However, the disclosure is not limited thereto. For example, the second reflective electrodes RL2 may include aluminum (Al).

The first step layer STPL1 may be disposed on the second reflective electrode RL2 in each of the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. The second step layer STPL2 may not be disposed on the first step layer STPL1 in the second sub-pixel SP2. For example, the second step layer STPL2 may not be disposed in the first sub-pixel SP1 or the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 (e.g., the distance between a lower surface of the second light-emitting stack ES2 of the second sub-pixel SP2 and an upper surface of the fourth reflective electrode RL4) to readily (or advantageously) reflect the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 (e.g., a distance between the lower surface of the third light-emitting stack ES3 of the third sub-pixel SP3 and an upper surface of the fourth reflective electrode RL4) to readily (or advantageously) reflect the light of the third color emitted from the light-emitting stack ES.

The first step layer STPL1 and the second step layer STPL2 may include (e.g., be formed of) silicon carbonitride (SiCN) or a silicon oxide (SiOx)-based inorganic film, but the embodiment of the specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the third reflective electrodes RL3 may include an alloy including at least one of the above-described metals. However, the disclosure is not limited thereto. For example, the third reflective electrodes RL3 may include titanium nitride (TiN).

For example, at least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to readily (or advantageously) reflect the light. Since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the fourth reflective electrodes RL4 may include an alloy including at least one of the above-described metals. However, the disclosure is not limited thereto. For example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer (e.g., a capping layer) through which light reflected by the reflective electrode layer RL passes, among light emitted from the light-emitting elements LE. The tenth insulating film INS10 may include (e.g., be formed of) a silicon oxide (SiOx)-based inorganic film, but the disclosure is not limited thereto.

Each of the tenth vias VA10 may penetrate the tenth insulating film INS10 and be electrically connected to the reflective electrode layer RL. The tenth vias VA10 may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the tenth vias VA10 may include an alloy including at least one of the above-described metals. However, the disclosure is not limited thereto.

The thicknesses of the tenth vias VA10 may be different in the first sub-pixel SP1, the second sub-pixel SP2, and the third sub-pixel SP3, and a resonance distance of light emitted from the light-emitting elements LE in at least one of the first sub-pixel SP1, the second sub-pixel SP2, or the third sub-pixel SP3 may be adjusted (or controlled). For example, the thickness of the tenth via VA10 in the third sub-pixel SP3 may be less than the thickness of the tenth via VA10 in each of the first sub-pixel SP1 and the second sub-pixel SP2. The thickness of the tenth via VA10 in the second sub-pixel SP2 may be smaller than the thickness of the tenth via VA10 in the first sub-pixel SP1. For example, the thicknesses of portions of the tenth insulating film INS10 in the first to third sub-pixels SP1, SP2, and SP3 may be different from each other. For example, the distance between the light-emitting stack ES and the reflective electrode layer RL may be different in the first sub-pixel SP1, the second sub-pixel SP2, and the third sub-pixel SP3.

To adjust the distance between the light-emitting stack ES (e.g., a first light-emitting stack ES1, a second light-emitting stack ES2, or a third light-emitting stack ES3) and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set. For example, at least one of the first and second step layers STPL1 and STPL2 may be disposed in each of the first to third sub-pixels SP1, SP2, and SP3, or at least one of the first and second step layers STPL1 and STPL2 may be omitted in each of the first to third sub-pixels SP1, SP2, and SP3. Thus, the thickness of the tenth insulating film INS10 and the distance between the light-emitting stack ES and the reflective electrode layer RL in the first to third sub-pixels SP1, SP2, and SP3 may be adjusted (or controlled).

The first electrode AND of each of the light-emitting elements LE may be disposed on the tenth insulating film INS10 and electrically connected to the tenth via VA10. The first electrode AND of each of the light-emitting elements LE may be electrically connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may include (e.g., be formed of) at least one of copper (Cu), aluminum (Al), tungsten (W), molybdenum (Mo), chromium (Cr), gold (Au), titanium (Ti), nickel (Ni), and neodymium (Nd). For example, the first electrode AND of each of the light-emitting elements LE may include an alloy including at least one of the above-described metals. However, the disclosure is not limited thereto. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover an edge of the first electrode AND of each of the light-emitting elements LE. The pixel defining film PDL may partition (e.g., divide or define) the first emission areas EA1, the second emission areas EA2, and the third emission areas EA3. For example, the pixel defining film PDL may have openings that expose (e.g., partially expose) the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include a first pixel defining film PDL1, a second pixel defining film PDL2, and a third pixel defining film PDL3. The first pixel defining film PDL1 may be disposed on the tenth insulating film INS10 and the first electrode AND of each of the light-emitting elements LE. The second pixel defining film PDL2 may be disposed on the first pixel defining film PDL1. The third pixel defining film PDL3 may be disposed on the second pixel defining film PDL2. The first pixel defining film PDL1, the second pixel defining film PDL2, and the third pixel defining film PDL3 may include (e.g., be formed of) a silicon oxide (SiOx)-based inorganic film, but the embodiment of the specification is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as a pixel defining film, the height of the pixel defining film may increase, and a first encapsulation inorganic film TFE1 may be cut off due to step coverage. The step coverage may refer to the ratio of the degree of thin film coated on an inclined portion to the degree of thin film coated on a flat portion. For example, the step coverage may refer to the state of film coverage when a film is deposited or coated on an uneven surface (e.g., a surface perpendicular to an evaporation source or a coating material) by sputtering, vapor deposition, coating, dropping, etc. The lower the step coverage, the more likely it is that the thin film will be cut off at inclined portions. For example, in case that a step coverage of a film is low, the film may be cut off at the inclined portions.

Therefore, the first pixel defining film PDL1, the second pixel defining film PDL2, and the third pixel defining film PDL3 may have a cross-sectional structure having a stepped portion, and the cut off of the first encapsulation inorganic film TFE1 due to the step coverage may be reduced or prevented. For example, in case that at least one of the first, second, and third pixel defining films PDL1, PDL2, and PDL3 has a stepped portion, a defect (e.g., cut off) of the first encapsulation inorganic film TFE1 may be reduced or prevented. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include the first light-emitting stack ES1 disposed in the first emission area EA1, the second light-emitting stack ES2 disposed in the second emission area EA2, and the third light-emitting stack ES3 disposed in the third emission area EA3. Although not shown in detail, the first light-emitting stack ES1 may include a hole injecting layer HIL, a hole transporting layer HTL, a first light-emitting layer EML1, an electron transporting layer ETL, and an electron injecting layer EIL, the second light-emitting stack ES2 may include the hole injecting layer HIL, the hole transporting layer HTL, a second light-emitting layer EML2, the electron transporting layer ETL, and the electron injecting layer EIL, and the third light-emitting stack ES3 may include the hole injecting layer HIL, the hole transporting layer HTL, a third light-emitting layer EML3, the electron transporting layer ETL, and the electron injecting layer EIL.

For example, the hole injecting layer HIL may be disposed on the first electrodes AND exposed by the openings of the pixel defining film PDL, the inner surfaces of the openings of the pixel defining film PDL, and the top surface of the pixel defining film PDL. The hole transporting layer HTL may be disposed on the hole injecting layer HIL.

The first to third light-emitting layers EML1, EML2, and EML3 may be respectively disposed in the openings of the pixel defining film PDL on the hole transporting layer HTL. The first light-emitting layer EML1 may be disposed in the opening of the pixel defining film PDL in the first emission area EA1, and may emit light of a first color, for example, red light. The second light-emitting layer EML2 may be disposed in the opening of the pixel defining film PDL in the second emission area EA2, and may emit light of a second color, for example, green light. The third light-emitting layer EML3 may be disposed in the opening of the pixel defining film PDL in the third emission area EA3, and may emit light of a third color, for example, blue light.

The electron transporting layer ETL may be disposed on the first to third light-emitting layers EML1, EML2, and EML3 and the hole transporting layer HTL. The electron injecting layer EIL may be disposed on the electron transporting layer ETL.

For example, although not shown, trenches (not shown) may be disposed between the first to third emission areas EA1, EA2, and EA3. The trenches may have a ring shape respectively adjacent to (e.g., surrounding) the first to third emission areas EA1, EA2, and EA3, and may penetrate the pixel defining film PDL. The hole injecting layer HIL and the hole transporting layer HTL formed on the first electrodes AND of the first to third emission areas EA1, EA2, and EA3 may be disconnected (or divided) from each other by the trenches. For example, the hole injecting layer HIL and the hole transporting layer HTL formed on the first electrodes AND of the first to third emission areas EA1, EA2, and EA3 may be electrically insulated from each other.

For example, the first to third light-emitting stacks ES1, ES2, and ES3 may be respectively disposed in the openings of the pixel defining film PDL, and may not be disposed on the pixel defining film PDL. The first to third light-emitting stacks ES1, ES2, and ES3 may be disconnected (or divided) from each other by the pixel defining film PDL. For example, the first to third light-emitting stacks ES1, ES2, and ES3 may be electrically insulated from each other.

The second electrode CAT may be disposed on the first to third light-emitting stacks ES1, ES2, and ES3. The second electrode CAT may include (e.g., be formed of) a transparent conductive material (TCO) or a semi-transmissive conductive material. The transparent conductive material (TCO) of the second electrode CAT may transmit light and include ITO, IZO, or the like. The semi-transmissive conductive material of the second electrode CAT may include magnesium (Mg), silver (Ag), an alloy of Mg and Ag, or the like. However, the disclosure is not limited thereto. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film (e.g., a first encapsulation inorganic film TFE1 and a second encapsulation inorganic film TFE2) to reduce or prevent oxygen or moisture from permeating into the display element layer EML. For example, the encapsulation layer TFE may include the first encapsulation inorganic film TFE1 and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may include (e.g., be formed of) titanium oxide (TiOx) or aluminum oxide (AlOx), but the embodiment of the specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing an adhesive strength (e.g., an interfacial adhesion) between the encapsulation layer TFE and the cover layer CVL. The adhesive layer APL may be an organic film including at least one of acrylic resin, epoxy resin, phenolic resin, polyamide resin, and polyimide resin. However, the disclosure is not limited thereto.

The cover layer CVL may be disposed on the adhesive layer APL. The cover layer CVL may be a glass substrate or a polymer resin. In case that the cover layer CVL is a glass substrate, the cover layer CVL may be attached onto the adhesive layer APL, and may serve as (e.g., be implemented with) an encapsulation substrate. In case that the cover layer CVL is a polymer resin, the polymer resin may be applied (e.g., directly applied, coated, or dropped) onto the adhesive layer APL.

The polarizing plate POL may be disposed on the cover layer CVL. The polarizing plate POL may be a structure for reducing or preventing reflection of external light. Thus, visibility (or image display quality) of the display device may be improved. The polarizing plate POL may include a linear polarizing plate and a phase retardation film. For example, the phase retardation film may be a λ/4 plate (quarter-wave plate), but the disclosure is not limited thereto.

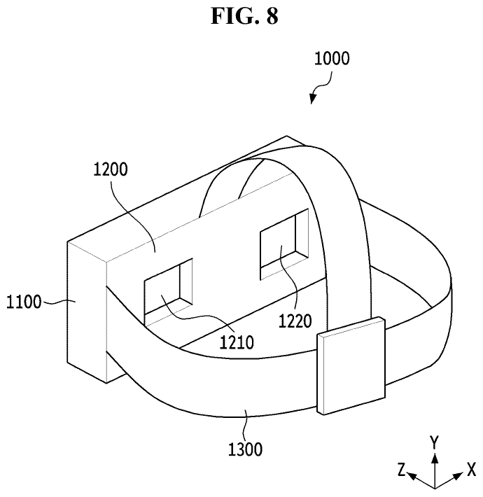

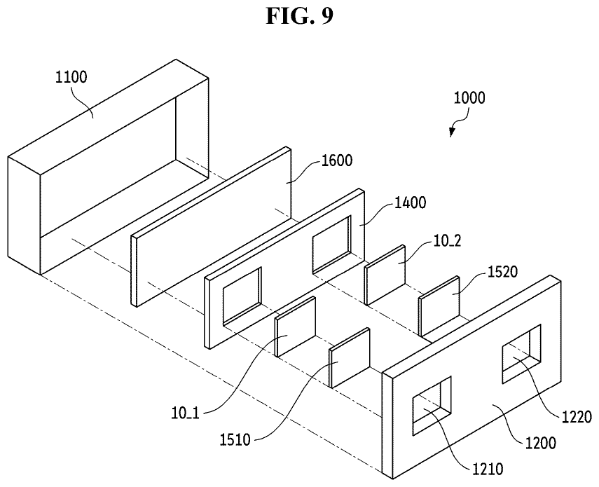

FIG. 8 is a schematic perspective view illustrating a head mounted display. FIG. 9 is a schematic exploded perspective view illustrating an example of the head mounted display shown in FIG. 8.

Referring to FIGS. 8 and 9, a head mounted display 1000 according to an embodiment may include a first display device 10_1, a second display device 102, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 102 may provide an image to the user's right eye. Since each of the first display device 10_1 and the second display device 10_2 is substantially the same as the display device 10 described in conjunction with FIGS. 1 and 2, detailed description of the same or similar constituent elements of the first display device 10_1 and the second display device 10_2 is omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 may support and fix the first display device 10_1, the second display device 102, and the control circuit board 1600.

The control circuit board 1600 may be disposed between the middle frame 1400 and the display device housing 1100. The control circuit board 1600 may be electrically connected to the first display device 10_1 and the second display device 10_2 through a connector. The control circuit board 1600 may convert an image source inputted from the outside into the digital video data DATA (e.g., refer to FIG. 2), and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. In other embodiments, the control circuit board 1600 may transmit the same digital video data DATA to the first display device 10_1 and the second display device 10_2.

The display device housing 1100 may accommodate the first display device 10_1, the second display device 102, the middle frame 1400, the first optical member 1510, the second optical member 1520, and the control circuit board 1600. The housing cover 1200 may cover an open surface of the display device housing 1100. The housing cover 1200 may include the first eyepiece 1210 at which the user's left eye is located and the second eyepiece 1220 at which the user's right eye is located. In FIGS. 8 and 9, the first eyepiece 1210 and the second eyepiece 1220 may be disposed separately, but the disclosure is not limited thereto. The first eyepiece 1210 and the second eyepiece 1220 may be combined to each other.

The first eyepiece 1210 may be aligned with the first display device 10_1 and the first optical member 1510. The second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 102 magnified as a virtual image by the second optical member 1520.

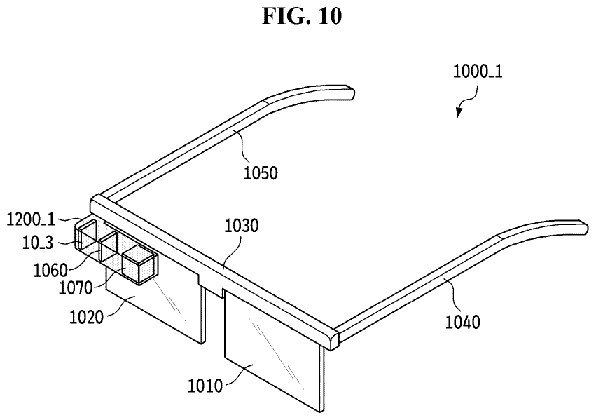

The head mounted band 1300 may secure the display device housing 1100 to the user's head, and the first eyepiece 1210 and the second eyepiece 1220 of the housing cover 1200 may remain located on the user's left and right eyes, respectively. In case that the display device housing 1100 is implemented to be lightweight and compact, the head mounted display 1000 may be provided in the form of glasses as shown in FIG. 10.

The head mounted display 1000 may further include a battery for supplying power, an external memory slot for accommodating an external memory, and an external connection port and a wireless communication module for receiving an image source. The external connection port may be a universe serial bus (USB) terminal, a display port, a high-definition multimedia interface (HDMI) terminal, or the like. The wireless communication module may be a 5G communication module, a 4G communication module, a Wi-Fi module, a Bluetooth module, or the like.

FIG. 10 is a schematic perspective view illustrating an example of a head mounted display.

Referring to FIG. 10, a head mounted display 10001 may be an eyeglasses-type display device in which a display device housing 1200_1 is implemented in a lightweight and compact manner. The head mounted display 10001 may include a display device 10_3, a left eye lens 1010, a right eye lens 1020, a support frame 1030, temples 1040 and 1050, an optical member 1060, an optical path conversion member 1070, and the display device housing 12001.

For example, the display device housing 12001 may include the display device 10_3, the optical member 1060, and the optical path conversion member 1070. The image displayed on the display device 103 may be magnified by the optical member 1060, and may be provided to the user's right eye through the right eye lens 1020 after the optical path of the display device 10_3 is changed by the optical path changing member 1070. As a result, the user may view an augmented reality image, through the right eye, in which a virtual image displayed on the display device 10_3 and a real image seen through the right eye lens 1020 are combined.

In FIG. 10, the display device housing 12001 may be disposed at the right end of the support frame 1030, but the disclosure is not limited thereto. For example, the display device housing 12001 may be disposed at the left end of the support frame 1030, and the image of the display device 10_3 may be provided to the user's left eye. For example, the display device housing 12001 may be disposed at the left and right ends of the support frame 1030, and the user may view the image displayed on the display device 10_3 through the left and right eyes.

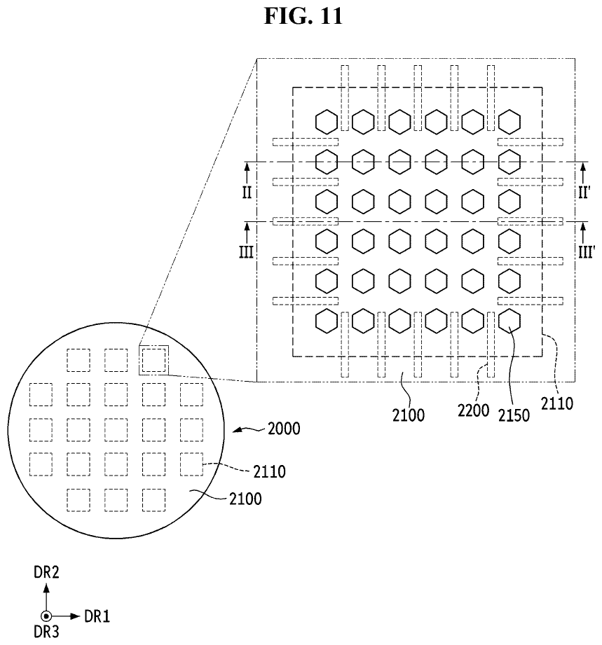

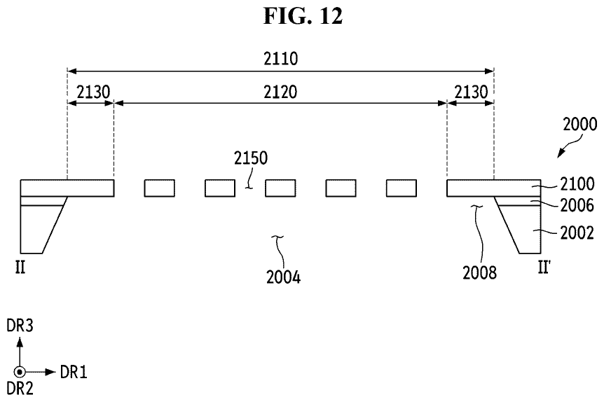

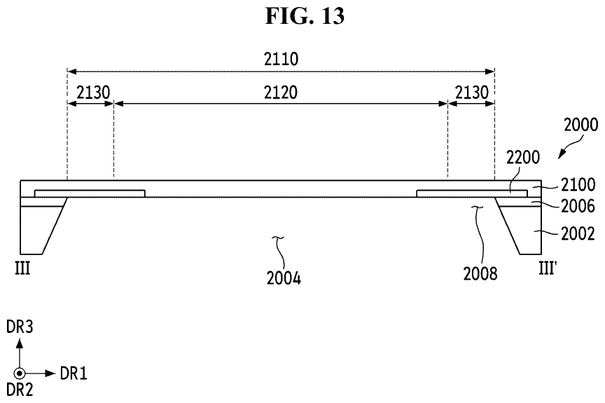

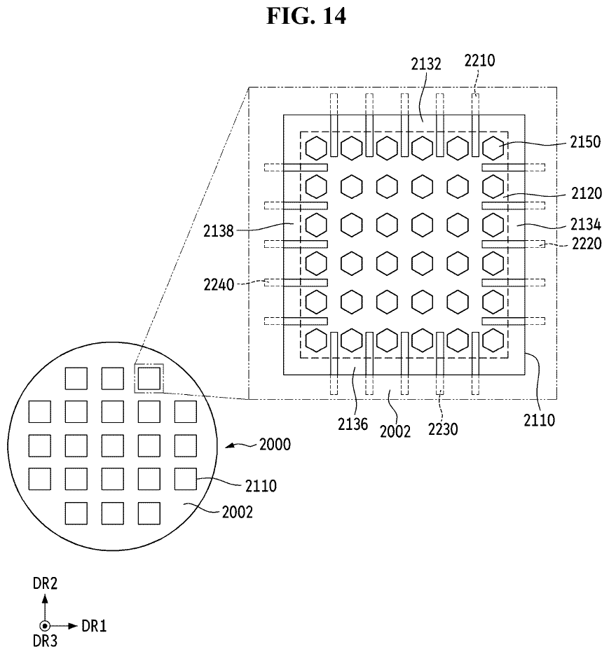

FIG. 11 is a schematic plan view illustrating a deposition mask according to an embodiment of the disclosure. FIG. 12 is a schematic cross-sectional view taken along line II-II′ shown in FIG. 11. FIG. 13 is a schematic cross-sectional view taken along line III-III′ shown in FIG. 11. FIG. 14 is a schematic bottom view illustrating the cell region shown in FIG. 11.

Referring to FIGS. 11 to 14, a deposition mask 2000 according to an embodiment of the disclosure may be used as a shadow mask in a deposition process for forming light-emitting layers of a light-emitting stack ES on a display substrate (or a backplane substrate) in order to manufacture a display panel 100 (see FIG. 1). For example, as illustrated in FIG. 7, the semiconductor backplane SBP and the light emitting element backplane EBP may be disposed on the display substrate, and the reflective electrodes RL and the insulating film INS10 may be disposed on the light emitting element backplane EBP. Electrode patterns, for example, the anode electrodes AND may be disposed on the insulating film INS10, and the anode electrodes AND may be electrically connected to the reflective electrodes RL through the vias VA10. As an example, the deposition mask 2000 may be used to form first light-emitting layers for emitting first light having a blue wavelength band on electrode patterns of the first emission areas EAL. As another example, the deposition mask 2000 may be used to form second light-emitting layers for emitting second light having a green wavelength band on electrode patterns of the second emission areas EA2. As still another example, the deposition mask 2000 may be used to form third light-emitting layers for emitting third light having a blue wavelength band on electrode patterns of the third emission areas EA3.

The deposition mask 2000 may include a substrate 2002 (or a mask substrate) and a membrane 2100 formed on the substrate 2002. For example, a silicon wafer may be used as the substrate 2002. The membrane 2100 may include (or be made of) an inorganic material and may be formed on the substrate 2002.

The membrane 2100 may include at least one cell region 2110. For example, the membrane 2100 may include cell regions 2110 that are disposed (e.g., arranged) in a matrix form along the first direction DR1 and the second direction DR2 intersecting (e.g., crossing) the first direction DR1. For example, the second direction DR2 may be a direction crossing (or perpendicular to) the first direction DR1. However, the disclosure is not limited thereto, and the arrangement direction and number of cell regions 2110 may be changed in various ways.

The substrate 2002 may have at least one cell opening 2004. For example, the substrate 2002 may include cell openings 2004 which respectively correspond to the cell regions 2110 of the membrane 2100. The cell openings 2004 may penetrate the substrate 2002 in a dry etching process, a wet etching process, or the like. Thus, the cell regions 2110 may be exposed through the cell openings 2004, respectively.

An inorganic film 2006, such as a silicon oxide film, may be formed on the substrate 2002. The membrane 2100 may be formed on the inorganic film 2006, and the inorganic film 2006 may function as (or be implemented with) an adhesive film between the substrate 2002 and the membrane 2100. The inorganic film 2006 may have openings 2008 that correspond to the cell openings 2004 of the substrate 2002. The cell regions 2110 of the membrane 2100 may be exposed through the cell openings 2004 of the substrate 2002 and the openings 2008 of the inorganic film 2006.

Each of the cell regions 2110 of the membrane 2100 may include pixel openings 2150. The pixel openings 2150 may function as (or be implemented with) paths for providing light-emitting materials in the deposition process for forming the light-emitting layers of the light-emitting stack ES (e.g., refer to FIG. 7). For example, as shown in FIG. 11, the pixel openings 2150 may be disposed (e.g., arranged) in a matrix form along the first direction DR1 and the second direction DR2, and may be formed by forming a second inorganic film used as the membrane 2100 on the inorganic film 2006 and partially removing the second inorganic film through an anisotropic etching process. For example, the second inorganic film may be formed on the inorganic film 2006, and the second inorganic film may be etched to form the membrane 2100 including the pixel openings 2150.

The membrane 2100 may include (or be made of) a material different from the inorganic film 2006. For example, the membrane 2100 may include (or be made of) silicon nitride, silicon oxynitride, or the like. However, the disclosure is not limited thereto, and the material constituting the membrane 2100 may be changed in various ways.

After the deposition mask 2000 is formed (or manufactured), the membrane 2100 may be deformed due to residual stress. In case that the residual stress remains in the membrane 2100, the deposition mask 2000 may not be brought into close contact with a backplane substrate in the deposition process. According to an embodiment of the disclosure, the deposition mask 2000 may include warpage control patterns 2200 for controlling the warpage of the cell regions 2110.

The warpage control patterns 2200 may be disposed between the substrate 2002 and the membrane 2100. For example, relatively great warpage may occur in an edge portion of each cell region 2110 of the membrane 2100. Accordingly, the warpage control patterns 2200 may be disposed (e.g., arranged) along the edge portion of the cell region 2110. For example, each of the cell regions 2110 may include a pattern region 2120 through which the pixel openings 2150 are formed, a peripheral region 2130 adjacent to (e.g., surrounding) the pattern region 2120. The warpage control patterns 2200 may be disposed (e.g., arranged) along the peripheral region 2130.

As shown in FIG. 14, the peripheral region 2130 may include a first peripheral region 2132 extending in the first direction DR1, a second peripheral region 2134 extending in the second direction DR2, a third peripheral region 2136 extending parallel to the first peripheral region 2132, and a fourth peripheral region 2138 extending parallel to the second peripheral region 2134.

As shown in FIG. 14, the warpage control patterns 2200 may include first warpage control patterns 2210 disposed (e.g., arranged) along the first peripheral region 2132 in the first direction DR1 and each extending in the second direction DR2, second warpage control patterns 2220 disposed (e.g., arranged) along the second peripheral region 2134 in the second direction DR2 and each extending in the first direction DR1, third warpage control patterns 2230 disposed (e.g., arranged) along the third peripheral region 2136 in the first direction DR1 and each extending in the second direction DR2, and fourth warpage control patterns 2240 disposed (e.g., arranged) along the fourth peripheral region 2138 in the second direction DR2 and each extending in the first direction DR1.

A portion of each of the warpage control patterns 2200 may be disposed on the inorganic film 2006, and a remaining portion of each of the warpage control patterns 2200 may be exposed through the cell opening 2004. The membrane 2100 may be disposed on the inorganic film 2006 and the warpage control patterns 2200. For example, each of the warpage control patterns 2200 may be in a cantilever shape and may support the edge portion of the cell region 2110. For example, the warpage control patterns 2200 may include a rigid material and support the edge portion of the cell region 2110 using a bending moment.

An end of each of the warpage control patterns 2200 may be disposed between the inorganic film 2006 and the membrane 2100. An intermediate portion of each of the warpage control patterns 2200 may support the peripheral region 2130 of the cell region 2110 above the cell opening 2004. Another end of each of the warpage control patterns 2200 may support the pattern region 2120 of the cell region 2110 above the cell opening 2004. For example, each of the warpage control patterns 2200 may extend across the peripheral region 2130 and protrude to the inside and outside of the peripheral region 2130. For example, the another end of each of the warpage control patterns 2200 may be disposed between the pixel openings 2150. As a result, the rigidity of the cell region 2110 may be increased by the warpage control patterns 2200. Accordingly, warpage of the cell region 2110 may be reduced. For example, the warpage control patterns 2200 may function as (or be implemented with) reinforcement patterns and increase the rigidity of the cell region 2110.

The warpage control patterns 2200 may include a metal material. For example, the warpage control patterns 2200 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the warpage control patterns 220 may include invar alloy or other alloy including at least one of the above-described materials. The warpage control patterns 2200 may be formed through a chemical vapor deposition process, an atomic layer deposition process, a physical vapor deposition process, an electroforming process, or the like.

The length, thickness, and width of the warpage control patterns 2200 may be appropriately adjusted (or controlled) according to the degree of deformation of the cell regions 2110. Thus, the warpage of the cell regions 2110 of the membrane 2100 may be readily controlled. As a result, the position alignment and size control of the light-emitting layers may be improved in the deposition process using the deposition mask 2000 according to the embodiment.

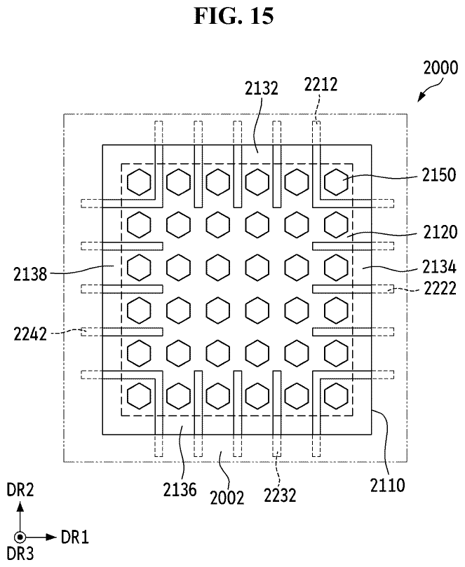

FIG. 15 is a schematic bottom view illustrating a deposition mask according to an embodiment of the disclosure.

Referring to FIG. 15, the deposition mask 2000 according to an embodiment of the disclosure may include the substrate 2002 having the cell opening 2004 (e.g., refer to FIG. 13), the membrane 2100 (e.g., refer to FIG. 13) having the cell region 2110 disposed above (or disposed on) the cell opening 2004, and the warpage control patterns 2200 (e.g., refer to FIG. 13) disposed between the substrate 2002 and the membrane 2100 to control warpage of the cell region 2110. In the embodiment, the deposition mask 2000 is different from the deposition mask 2000 of FIGS. 11 to 14 at least in the warpage control patterns 2200. Thus, detailed description of the same or similar constituent elements is omitted.

According to the embodiment, the warpage control patterns 2200 may include first warpage control patterns 2212 disposed (e.g., arranged) along the first peripheral region 2132 in the first direction DR1 and each extending in the second direction DR2, second warpage control patterns 2222 disposed (e.g., arranged) along the second peripheral region 2134 in the second direction DR2 and each extending in the first direction DR1, third warpage control patterns 2232 disposed (e.g., arranged) along the third peripheral region 2136 in the first direction DR1 and each extending in the second direction DR2, and fourth warpage control patterns 2242 disposed (e.g., arranged) along the fourth peripheral region 2138 in the second direction DR2 and each extending in the first direction DR1.

For example, as shown in FIG. 15, among the first and second warpage control patterns 2212 and 2222, a first warpage control pattern 2212 (e.g., the rightmost first warpage control pattern 2212) and a second warpage control pattern 2222 (e.g., the uppermost second warpage control pattern 2222) that are adjacent to each other may be connected to each other. For example, the rightmost first warpage control pattern 2212 may extend toward the uppermost second warpage control pattern 2222 adjacent to the rightmost first warpage control pattern 2212. Among the second and third warpage control patterns 2222 and 2232, a second warpage control pattern 2222 (e.g., the lowermost second warpage control pattern 2222) and a third warpage control pattern 2232 (e.g., the rightmost third warpage control pattern 2232) that are adjacent to each other may be connected to each other. For example, the lowermost second warpage control pattern 2222 may extend toward the rightmost third warpage control pattern 2232 adjacent to the lowermost second warpage control pattern 2222. Among the third and fourth warpage control patterns 2232 and 2242, a third warpage control pattern 2232 (e.g., the leftmost third warpage control pattern 2232) and a fourth warpage control pattern 2242 (e.g., the lowermost fourth warpage control pattern 2242) that are adjacent to each other may be connected to each other. For example, the leftmost third warpage control pattern 2232 may extend toward the lowermost fourth warpage control pattern 2242 adjacent to the leftmost third warpage control pattern 2232. Among the fourth and first warpage control patterns 2242 and 2212, a fourth warpage control pattern 2242 (e.g., the uppermost fourth warpage control pattern 2242) and a first warpage control pattern 2212 (e.g., the leftmost first warpage control pattern 2212) that are adjacent to each other may be connected to each other. For example, the uppermost fourth warpage control pattern 2242 may extend toward the leftmost first warpage control pattern 2212 adjacent to the uppermost fourth warpage control pattern 2242.

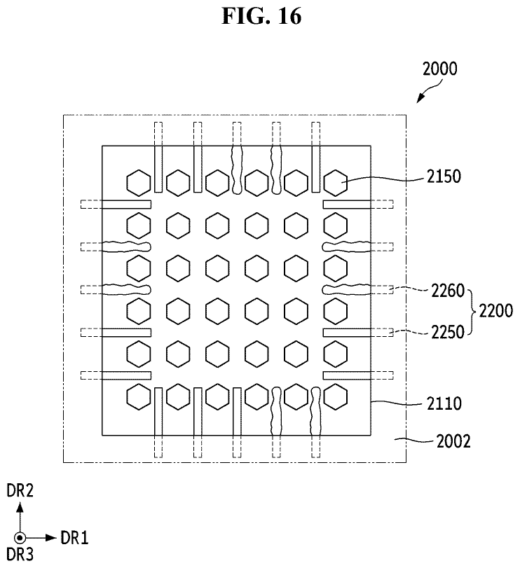

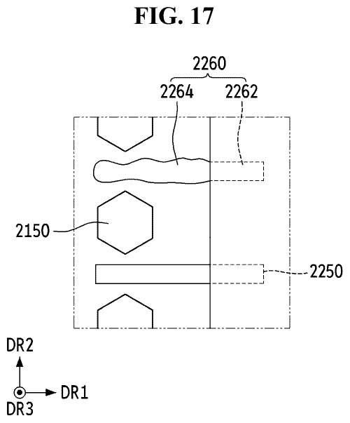

FIG. 16 is a schematic bottom view illustrating a deposition mask according to an embodiment of the disclosure. FIG. 17 is a schematic enlarged bottom view illustrating the first warpage control pattern and the second warpage control pattern shown in FIG. 16.

Referring to FIGS. 16 and 17, the deposition mask 2000 according to an embodiment of the disclosure may include the substrate 2002 having the cell opening 2004 (e.g., refer to FIG. 13), the membrane 2100 (e.g., refer to FIG. 13) having the cell region 2110 disposed above (or disposed on) the cell opening 2004, and the warpage control patterns 2200 disposed between the substrate 2002 and the membrane 2100. The warpage control patterns 2200 may control warpage of the cell region 2110. In the embodiment, the deposition mask 2000 is different from the deposition mask 2000 of FIGS. 11 to 14 at least in the warpage control patterns 2200. Thus, detailed description of the same or similar constituent elements is omitted.

According to the embodiment, the warpage control patterns 2200 may include a metal material. For example, the warpage control patterns 2200 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the warpage control patterns 2200 may include invar alloy or other alloy including at least one of the above-described materials. The warpage control patterns 2200 may be formed through a chemical vapor deposition process, an atomic layer deposition process, a physical vapor deposition process, an electroforming process, or the like. For example, the warpage control patterns 2200 may include first warpage control patterns 2250 and second warpage control patterns 2260 having a shape different from that of the first warpage control patterns 2250.

As shown in FIG. 17, each of the second warpage control patterns 2260 may include a first pattern portion 2262 including (or made of) the aforementioned metal material, and a second pattern portion 2264 formed by melting and solidifying the metal material. The shape of the second pattern portion 2264 may be changed during the melting and solidifying processes. For example, after a deposition mask including the first warpage control patterns 2250 is formed (or manufactured), the warpage of the cell regions 2110 may be measured. At least one of the first warpage control patterns 2250 may be melted and solidified according to the measured degree of warpage of the cell regions 2110 to form at least one second warpage control pattern 2260. The second warpage control pattern 2260 may apply a tensile force to the cell region 2110 during the melting and solidifying processes, and the warpage of the cell region 2110 may be reduced. In other embodiments, the melting and solidifying processes may relieve stress and deformation of the deposition mask 2000, and the warpage of the cell region 2110 may be reduced. For example, a laser beam may be irradiated to at least one of the first warpage control patterns 2250 through the cell opening 2004, and the at least one of the first warpage control patterns 2250 may be partially melted. The molten portion may be solidified at the room temperature, and the second warpage control pattern 2260 may be formed.

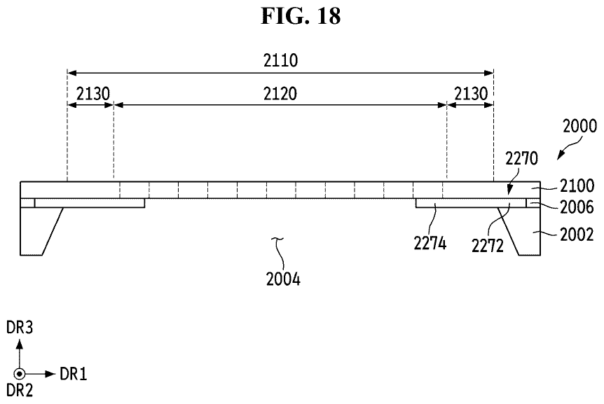

FIG. 18 is a schematic cross-sectional view illustrating a deposition mask according to an embodiment of the disclosure.

Referring to FIG. 18, the deposition mask 2000 according to an embodiment of the disclosure may include the substrate 2002 having the cell opening 2004, the membrane 2100 having the cell region 2110 disposed above (or disposed on) the cell opening 2004, and warpage control patterns 2270 disposed between the substrate 2002 and the membrane 2100 to control warpage of the cell region 2110. In the embodiment, the deposition mask 2000 is different from the deposition mask 2000 of FIGS. 11 to 14 at least in the warpage control patterns 2270. Thus, detailed description of the same or similar constituent elements is omitted.

According to the embodiment, the warpage control patterns 2270 may be disposed on the substrate 2002. The inorganic film 2006 may be disposed on the substrate 2002, and the membrane 2100 may be disposed on the warpage control patterns 2270 and the inorganic film 2006. The warpage control patterns 2270 and the inorganic film 2006 may have a same thickness (or substantially the same thickness). For example, the inorganic film 2006 may be disposed on the top surface of the substrate 2002 and the side surfaces of the warpage control patterns 2270.

A portion 2272 of each of the warpage control patterns 2270 may be disposed between the substrate 2002 and the membrane 2100, and a remaining portion 2274 of each of the warpage control patterns 2270 may extend inwardly of the cell opening 2004 across the peripheral region 2130 of the cell region 2110. The cell region 2110 of the membrane 2100 may be supported by the remaining portions 2274 of the warpage control patterns 2270. The remaining portions 2274 of the warpage control patterns 2270 may be exposed through the cell opening 2004 of the substrate 2002. As a result, the cell regions 2110 of the membrane 2100 may be supported by the warpage control patterns 2270, and the deformation of the cell regions 2110 of the membrane 2100 may be reduced.

The warpage control patterns 2270 may include a metal material. For example, the warpage control patterns 2270 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the warpage control patterns 2270 may include invar alloy and other alloy including at least one of the above-described materials. The warpage control patterns 2270 may be formed through a chemical vapor deposition process, an atomic layer deposition process, a physical vapor deposition process, an electroforming process, or the like.

For example, although not shown, the warpage control patterns 2270 may include first warpage control patterns and second warpage control patterns that have a shape different from that of the first warpage control patterns. Each of the second warpage control patterns may include a first pattern portion including (or made of) the aforementioned metal material and a second pattern portion formed by melting and solidifying the metal material. Detailed description of the same or similar constituent elements shown in FIG. 17 is omitted. The shape of the second pattern portion may be changed during the melting and solidifying processes. For example, the first and second warpage control patterns 2250 and 2260 aforementioned with reference to FIGS. 16 and 17 may be applied to the embodiment.

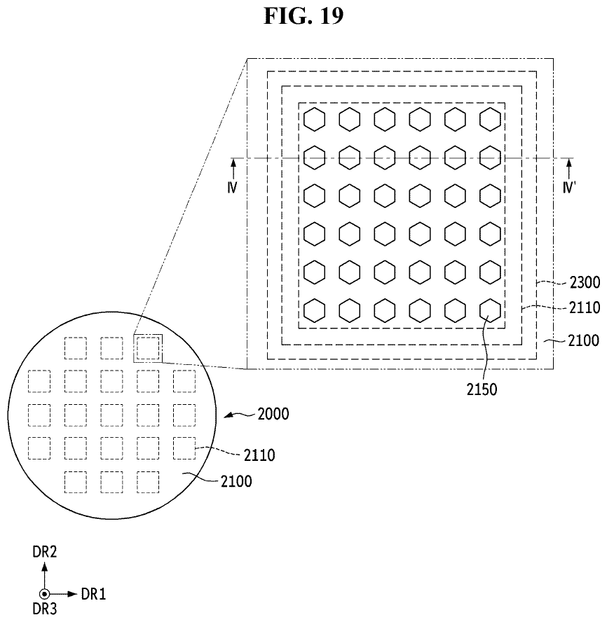

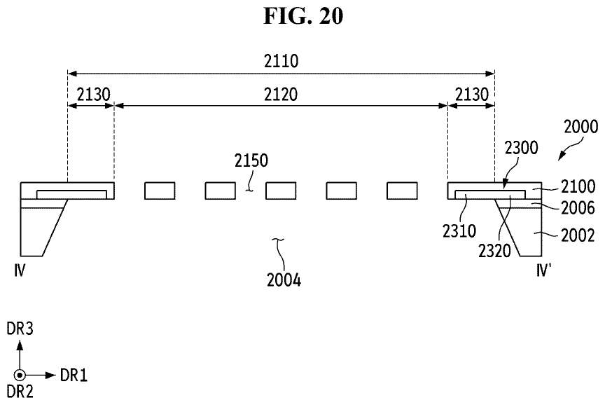

FIG. 19 is a schematic plan view illustrating a deposition mask according to an embodiment of the disclosure. FIG. 20 is a schematic cross-sectional view taken along line IV-IV′ shown in FIG. 19.

Referring to FIGS. 19 and 20, the deposition mask 2000 according to an embodiment of the disclosure may include the substrate 2002 having the cell opening 2004, the membrane 2100 having the cell region 2110 disposed above (or disposed on) the cell opening 2004, and a reinforcement pattern 2300 that extends along the edge portion of the cell region 2110 between the substrate 2002 and the membrane 2100 and supports the edge portion of the cell region 2110 to reduce warpage of the cell region 2110. In the embodiment, the deposition mask 2000 is different from the deposition mask 2000 of FIGS. 11 to 14 at least in the reinforcement pattern 2300. Thus, detailed description of the same or similar constituent elements is omitted.

The inorganic film 2006, such as a silicon oxide film, may be disposed on the substrate 2002, and the reinforcement pattern 2300 may be disposed on the inorganic film 2006 and reduce warpage of the cell region 2110. The membrane 2100 may be disposed on the inorganic film 2006 and the reinforcement pattern 2300, and may include the cell regions 2110. For example, according to the embodiment, each of the cell regions 2110 may include the pattern region 2120 through which the pixel openings 2150 are formed and the peripheral region 2130 that is disposed adjacent to (e.g., surrounds) the pattern region 2120. The reinforcement pattern 2300 may have a ring shape extending along the peripheral region 2130.

The reinforcement pattern 2300 may include a metal material. For example, the reinforcement pattern 2300 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the reinforcement pattern 2300 may include invar alloy or other alloy including at least one of the above-described materials. The reinforcement pattern 2300 may be formed through a chemical vapor deposition process, an atomic layer deposition process, a physical vapor deposition process, an electroforming process, or the like.

The substrate 2002 may have the cell opening 2004 that exposes the cell region 2110 of the membrane 2100. The reinforcement pattern 2300 may have an inner ring region 2310 exposed through the cell opening 2004 and an outer ring region 2320 disposed between the inorganic film 2006 and the membrane 2100. The peripheral region 2130 of the cell region 2110 may be disposed on the inner ring region 2310 of the reinforcement pattern 2300. As a result, the inner ring region 2310 of the reinforcement pattern 2300 may support the peripheral region 2130 of the cell region 2110. Thus, warpage or deformation of the cell region 2110 of the membrane 2100 may be reduced or prevented.

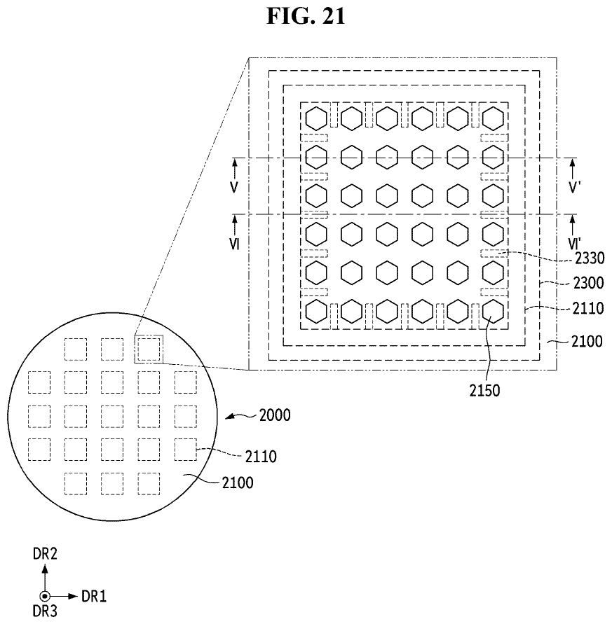

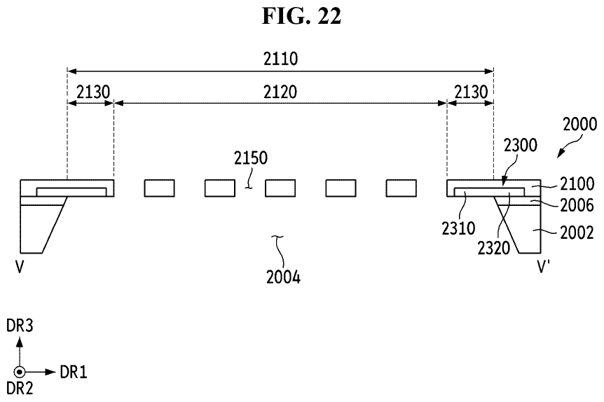

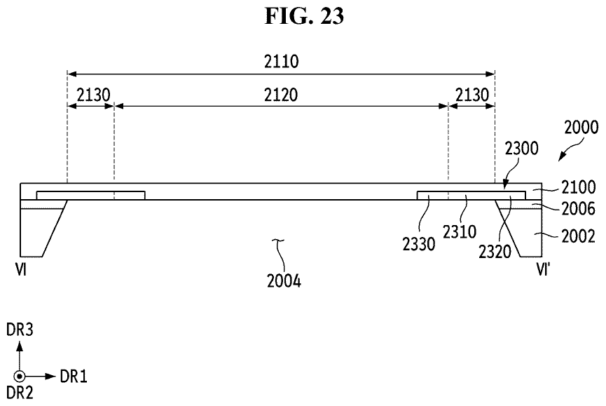

FIG. 21 is a schematic plan view illustrating a deposition mask according to an embodiment of the disclosure. FIG. 22 is a schematic cross-sectional view taken along line V-V′ shown in FIG. 21, and FIG. 23 is a schematic cross-sectional view taken along line VI-VI′ shown in FIG. 21.

Referring to FIGS. 21 to 23, the deposition mask 2000 according to an embodiment of the disclosure may include the substrate 2002 having the cell opening 2004, the membrane 2100 having the cell region 2110 disposed above (or disposed on) the cell opening 2004, the reinforcement pattern 2300 disposed between the substrate 2002 and the membrane 2100 to reduce warpage of the cell region 2110, and warpage control patterns 2330 for controlling warpage of the cell region 2110. In the embodiment, the deposition mask 2000 is different from the deposition mask 2000 of FIGS. 11 to 14 at least in the reinforcement pattern 2300 and the warpage control patterns 2330. Thus, detailed description of the same or similar constituent elements is omitted.

The inorganic film 2006, such as a silicon oxide film, may be disposed on the substrate 2002, and the reinforcement pattern 2300 may be disposed on the inorganic film 2006 and reduce warpage of the cell region 2110. The membrane 2100 may be disposed on the inorganic film 2006 and the reinforcement pattern 2300, and may include the cell regions 2110. Each of the cell regions 2110 may include the pattern region 2120 through which the pixel openings 2150 are formed and the peripheral region 2130 that is disposed adjacent to (e.g., surrounds) the pattern region 2120. The reinforcement pattern 2300 may have a ring shape extending along the peripheral region 2130.

The substrate 2002 may have the cell opening 2004 that exposes the cell region 2110 of the membrane 2100. The reinforcement pattern 2300 may have the inner ring region 2310 exposed through the cell opening 2004 and the outer ring region 2320 disposed between the inorganic film 2006 and the membrane 2100. The peripheral region 2130 of the cell region 2110 may be disposed on the inner ring region 2310 of the reinforcement pattern 2300.

According to the embodiment, the warpage control patterns 2330 may extend from the reinforcement pattern 2300 toward the pattern region 2120. For example, each of the warpage control patterns 2330 may extend from the inner ring region 2310 of the reinforcement pattern 2300 toward the pattern region 2120 and may be disposed between the pixel openings 2150. As a result, the peripheral region 2130 of the cell region 2110 may be supported by the inner ring region 2310 of the reinforcement pattern 2300, and the pattern region 2120 of the cell region 2110 may be supported by the warpage control patterns 2330.

The reinforcement pattern 2300 and the warpage control patterns 2330 may include a metal material. For example, the reinforcement pattern 2300 and the warpage control patterns 2330 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the reinforcement pattern 2300 and the warpage control patterns 2330 may include invar alloy or other alloy including at least one of the above-described materials. The reinforcement pattern 2300 and the warpage control patterns 2330 may be formed simultaneously through a chemical vapor deposition process, an atomic layer deposition process, a physical vapor deposition process, an electroforming process, or the like.

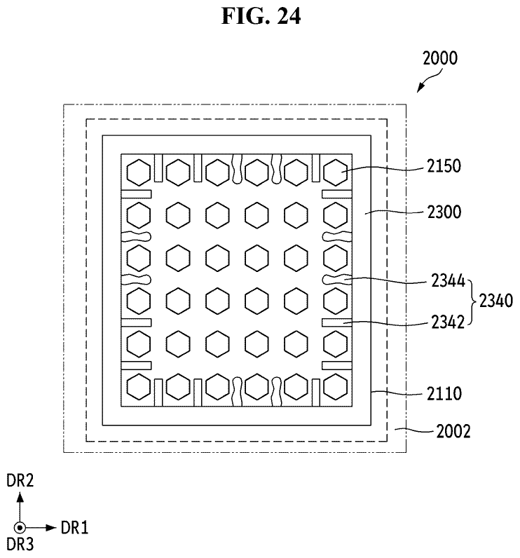

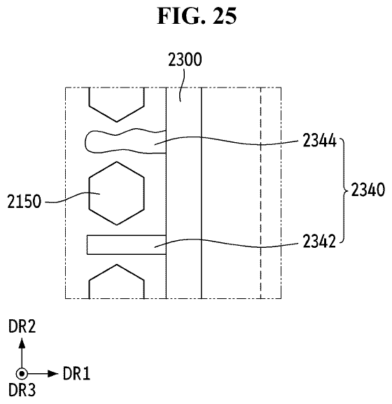

FIG. 24 is a schematic bottom view illustrating a deposition mask according to an embodiment of the disclosure. FIG. 25 is a schematic enlarged bottom view illustrating the first warpage control pattern and the second warpage control pattern shown in FIG. 24.

Referring to FIGS. 24 and 25, the deposition mask 2000 according to an embodiment of the disclosure may include the substrate 2002 having the cell opening 2004 (e.g., refer to FIG. 23), the membrane 2100 (e.g., refer to FIG. 23) having the cell region 2110 disposed above (or disposed on) the cell opening 2004, the reinforcement pattern 2300 disposed between the substrate 2002 and the membrane 2100 to reduce warpage of the cell region 2110, and warpage control patterns 2340 for controlling warpage of the cell region 2110. In the embodiment, the deposition mask 2000 is different from the deposition mask 2000 of FIGS. 11 to 14 and 21 to 23 at least in the warpage control patterns 2340. Thus, detailed description of the same or similar constituent elements is omitted.

According to the embodiment, the warpage control patterns 2340 may include a metal material. For example, the warpage control patterns 2340 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the warpage control patterns 2340 may include invar alloy or other alloy including at least one of the above-described materials. The warpage control patterns 2340 may be formed through a chemical vapor deposition process, an atomic layer deposition process, a physical vapor deposition process, an electroforming process, or the like. For example, the warpage control patterns 2340 may include first warpage control patterns 2342 and second warpage control patterns 2344 having a shape different from that of the first warpage control patterns 2342.

Each of the second warpage control patterns 2344 may be formed by melting and solidifying a metal material, as shown in FIG. 25. The shape of the second warpage control patterns 2344 may be changed during the melting and solidifying processes.

For example, after the deposition mask 2000 including the first warpage control patterns 2342 is formed (or manufactured), warpage of the cell regions 2110 may be measured. At least one of the first warpage control patterns 2342 may be melted and solidified according to the measured degree of warpage of the cell regions 2110 to form at least one second warpage control pattern 2344. The second warpage control pattern 2344 may apply a tensile force to the cell region 2110 during the melting and solidifying processes, and the warpage of the cell region 2110 may be reduced. In other embodiments, the melting and solidifying processes may relieve stress and deformation of the deposition mask 2000, and the warpage of the cell region 2110 may be reduced. For example, a laser beam may be irradiated to at least one of the first warpage control patterns 2342 through the cell opening 2004 to melt at least one of the first warpage control patterns 2342. The molten portion may be solidified at room temperature, and the second warpage control pattern 2344 may be formed.

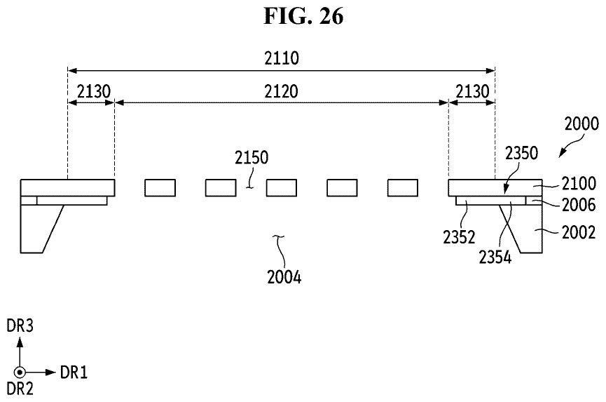

FIG. 26 is a schematic cross-sectional view illustrating a deposition mask according to an embodiment of the disclosure.

Referring to FIG. 26, the deposition mask 2000 according to an embodiment of the disclosure may include the substrate 2002 having the cell opening 2004, the membrane 2100 having the cell region 2110 disposed above (or disposed on) the cell opening 2004, and a reinforcement pattern 2350 disposed between the substrate 2002 and the membrane 2100 to reduce warpage of the cell region 2110. In the embodiment, the deposition mask 2000 is different from the deposition mask 2000 of FIGS. 11 to 14 and 19 to 20 at least in the reinforcement pattern 2350. Thus, detailed description of the same or similar constituent elements is omitted.

According to the embodiment, the reinforcement pattern 2350 may be disposed on the substrate 2002. The inorganic film 2006 may be disposed on the substrate 2002, and the membrane 2100 may be disposed on the reinforcement pattern 2350 and the inorganic film 2006. The reinforcement pattern 2350 and the inorganic film 2006 may have a same thickness (or substantially the same thickness). For example, the inorganic film 2006 may be disposed on the top surface of the substrate 2002 and the side surfaces of the reinforcement pattern 2350.

An inner ring region 2352 of the reinforcement pattern 2350 may be exposed through the cell opening 2004 of the substrate 2002, and an outer ring region 2354 of the reinforcement pattern 2350 may be disposed between the substrate 2002 and the membrane 2100. The cell region 2110 of the membrane 2100 may be supported by the inner ring region 2352 of the reinforcement pattern 2350. Thus, warpage or deformation of the cell regions 2110 of the membrane 2100 may be reduced.

The reinforcement pattern 2350 may include a metal material. For example, the reinforcement pattern 2350 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the reinforcement pattern 2350 may include invar alloy or other alloy including at least one of the above-described materials. The reinforcement pattern 2350 may be formed through a chemical vapor deposition process, an atomic layer deposition process, a physical vapor deposition process, an electroforming process, or the like.

For example, although not shown, the deposition mask 2000 may include warpage control patterns extending from the reinforcement pattern 2350. For example, the warpage control patterns 2330 aforementioned with reference to FIGS. 21 to 23 may be applied to the embodiment. For example, the first and second warpage control patterns 2342 and 2344 aforementioned with reference to FIGS. 24 and 25 may be applied to the embodiment.

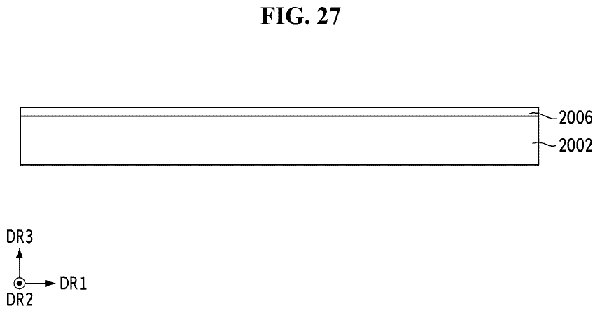

FIGS. 27 to 32 are schematic cross-sectional views illustrating a method of manufacturing a deposition mask according to an embodiment of the disclosure.

Referring to FIG. 27, the inorganic film 2006 may be formed on the substrate 2002. For example, a silicon wafer may be used as the substrate 2002, and a silicon oxide film used as the inorganic film 2006 may be formed on the substrate 2002. For example, the silicon oxide film may be formed (e.g., oxidized, deposited, or the like) on the substrate 2002 to form the inorganic film 2006. The silicon oxide film may be formed through a thermal oxidation process or a chemical vapor deposition process. However, the disclosure is not limited thereto, and the inorganic film 2006 may be formed using other materials.

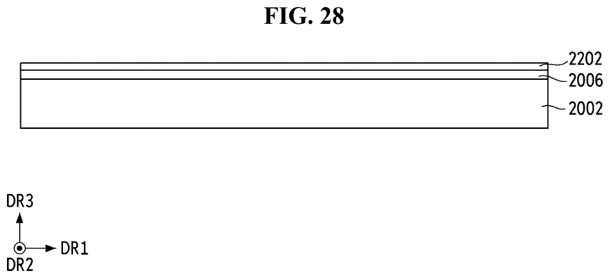

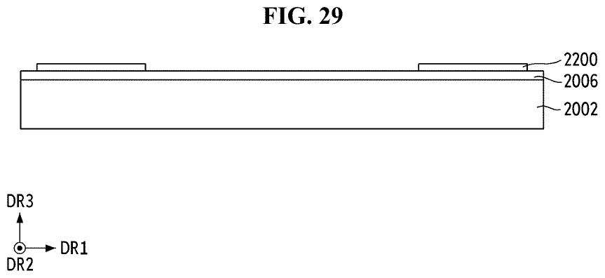

Referring to FIGS. 28 and 29, the warpage control patterns 2200 may be formed on the inorganic film 2006. The warpage control patterns 2200 may include a metal material. For example, the warpage control patterns 2200 may include (or be made of) a metal material such as tungsten (W), molybdenum (Mo), chromium (Cr), titanium (Ti), iron (Fe), nickel (Ni), tungsten nitride (WN), and titanium nitride (TiN). However, the disclosure is not limited thereto, and the warpage control patterns 2200 may include invar alloy or other alloy including at least one of the above-described materials.

For example, as shown in FIG. 28, a metal film 2202 including (or made of) the aforementioned metal material may be formed (e.g., deposited) on the inorganic film 2006. For example, the metal film 2202 may be formed through a chemical vapor deposition process, an atomic layer deposition process, a physical vapor deposition process, an electroforming process, or the like.

As shown in FIG. 29, the warpage control patterns 2200 may be formed on the inorganic film 2006 by patterning the metal film 2202. For example, a photoresist pattern (not shown), which exposes the remaining portions except for the portions where the warpage control patterns 2200 will be formed, may be formed on the metal film 2202, and an anisotropic etching process using the photoresist pattern as an etch mask may form the warpage control patterns 2200 from the metal film 2202. The warpage control patterns 2200 of FIG. 29 and those aforementioned with reference to FIGS. 11 to 15 may have a same shape and a same arrangement (or substantially the same shape and arrangement). After the warpage control patterns 2200 are formed, the photoresist pattern may be removed through a strip and/or ashing process.

For example, although not shown, the inorganic film 2006 and the warpage control patterns 2200 may be formed on the substrate 2002. For example, after the warpage control patterns 2270 are formed on the substrate 2002 as shown in FIG. 18, the inorganic film 2006 may be formed on the substrate 2002 and the warpage control patterns 2270. A planarization process such as a chemical mechanical polishing (CMP) process may expose the warpage control patterns 2270.

For example, a reinforcement pattern having a ring shape may be formed on the inorganic film 2006 instead of the warpage control patterns 2200. For example, the reinforcement pattern 2300 aforementioned with reference to FIGS. 19 and 20 may be formed on the inorganic film 2006. The reinforcement pattern 2300 may include (or be made of) a metal material including at least one of tungsten (W), molybdenum (Mo), chromium (Cr), titanium (Ti), iron (Fe), nickel (Ni), tungsten nitride (WN), and titanium nitride (TiN). However, the disclosure is not limited thereto, and the reinforcement pattern 2300 may include invar alloy or other alloy including at least one of the above-described materials.

For example, a reinforcement pattern having a ring shape may be formed on the inorganic film 2006 simultaneously with the warpage control patterns. The reinforcement pattern and the warpage control patterns may include (or be made of) a same material. As aforementioned with reference to FIGS. 21 to 23, the warpage control patterns 2330 may extend from the inner portion of the reinforcement pattern 2300.

For example, a reinforcement pattern may be formed on the substrate 2002. For example, the reinforcement pattern 2350 aforementioned with reference to FIG. 26 may be formed on the substrate 2002. The reinforcement pattern 2350 may include (or be made of) a metal material including tungsten (W), molybdenum (Mo), chromium (Cr), titanium (Ti), iron (Fe), nickel (Ni), tungsten nitride (WN), and titanium nitride (TiN). However, the disclosure is not limited thereto, and the reinforcement pattern 2350 may include invar alloy or other alloy including at least one of the above-described materials.

For example, a reinforcement pattern having a ring shape may be formed on the substrate 2002 simultaneously with the warpage control patterns. The reinforcement pattern and the warpage control patterns may include (or be made of) a same material.

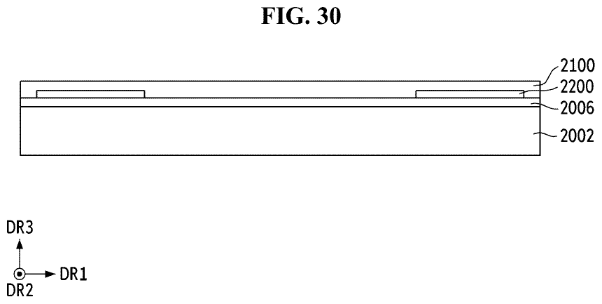

Referring to FIG. 30, the membrane 2100 may be formed on the inorganic film 2006 and the warpage control patterns 2200. The membrane 2100 may include silicon nitride or silicon oxynitride, and may be formed through a chemical vapor deposition process. However, the membrane 2100 may be formed using other materials, and the scope of the disclosure is not limited by the materials constituting the membrane 2100.

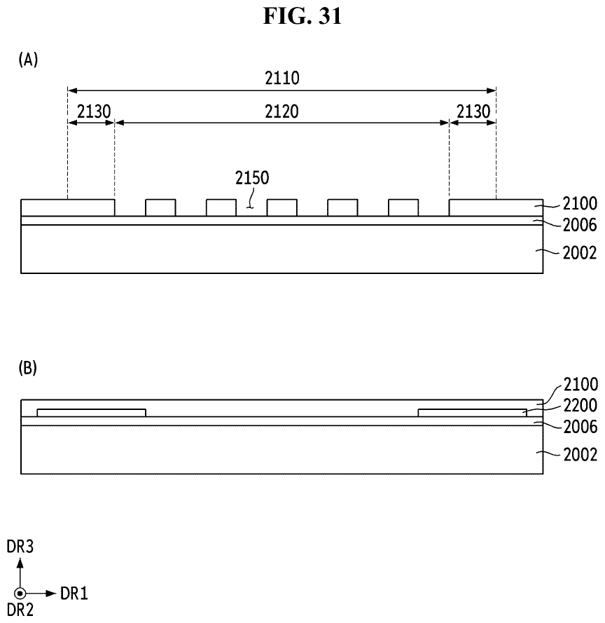

Referring to FIG. 31, the membrane 2100 may be patterned to form at least one cell region 2110. For example, the membrane 2100 may include the cell regions 2110, and each cell region 2110 may have the pixel openings 2150. For example, a photoresist pattern (not shown), which exposes the portions where the pixel openings 2150 will be formed, may be formed on the membrane 2100. An anisotropic etching process using the photoresist pattern as an etch mask may form the cell regions 2110 having the pixel openings 2150. The inorganic film 2006 may function as (or be implemented with) an etch stop layer in the anisotropic etching process, and the cell regions 2110 may partially overlap the warpage control patterns 2200 in a plan view. After the cell regions 2110 is formed, the photoresist pattern may be removed through a strip and/or ashing process.

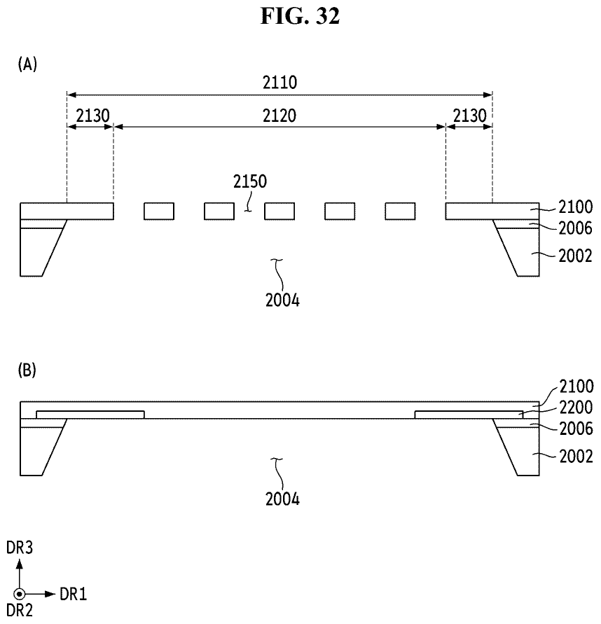

Referring to FIG. 32, the substrate 2002 may be partially etched to form the cell openings 2004 that expose the cell regions 2110. For example, after a photoresist pattern or hard mask pattern, which exposes the portions where the cell openings 2004 will be formed, is formed on the rear surface of the substrate 2002, the cell openings 2004 exposing the cell regions 2110 may be formed by performing a wet or dry etching process using the photoresist pattern or the hard mask pattern as an etch mask.

An etching process may partially remove the inorganic film 2006. The inorganic film 2006 may be partially removed, and the cell regions 2110 of the membrane 2100 may be exposed through the cell openings 2004.

After the cell openings 2004 are formed, the warpage control patterns 2200 may be partially exposed through the cell openings 2004, and may be disposed (e.g., arranged) along the edge portions of the cell regions 2110 as shown in FIG. 14. For example, a portion of each of the warpage control patterns 2200 may be disposed between the substrate 2002 and the membrane 2100, and the remaining portion of each of the warpage control patterns 2200 may be exposed through the cell opening 2004 and support the cell regions 2110 of the membrane 2100.

According to the embodiment, after the deposition mask 2000 as described above is formed (or manufactured), warpage of the cell region 2110 may be measured. A step of controlling the warpage of the cell region 2110 may be performed based on the measurement result of the warpage of the cell region 2110. For example, a distance sensor (not shown) may be placed above the deposition mask 2000 and a distance to the cell region 2110 may be measured using the distance sensor. The warpage of the cell region 2110 may be calculated based on the measured distance.

After the warpage state of the cell region 2110 as described above is formed (or manufactured), at least one of the warpage control patterns 2200 exposed through the cell opening 2004 may be melted and solidified at room temperature based on the measurement result. Thus, the warpage of the cell region 2110 may be controlled. For example, during the process of melting and solidifying at least one warpage control pattern 2200, a tensile force may be applied to the cell region 2110, and the warpage of the cell region 2110 may be reduced. In other embodiments, the melting and solidifying processes may relieve stress and deformation of the deposition mask 2000, and the warpage of the cell region 2110 may be reduced. For example, a laser beam may be irradiated to at least one of the warpage control patterns 2200 through the cell opening 2004, and the at least one warpage control pattern 2200 may be melted.

The above description is an example of technical features of the disclosure, and those skilled in the art to which the disclosure pertains will be able to make various modifications and variations. Thus, the embodiments of the disclosure described above may be implemented separately or in combination with each other.

Therefore, embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition mask comprising:
a membrane comprising a cell region disposed on a cell opening of a substrate; and
a plurality of warpage control patterns disposed along an edge portion of the cell region between the substrate and the membrane and supporting the edge portion of the cell region in a cantilever shape to control warpage of the cell region.

2. The deposition mask of claim 1, wherein the plurality of warpage control patterns comprise a metal material.

3. The deposition mask of claim 2, wherein the plurality of warpage control patterns comprise:
first warpage control patterns; and
at least one second warpage control pattern having a shape different from that of the first warpage control patterns.

4. The deposition mask of claim 3, wherein the at least one second warpage control pattern comprises:
a first pattern portion including the metal material; and
a second pattern portion formed by melting and solidifying the metal material.

5. The deposition mask of claim 1, wherein
the cell region comprises:
a pattern region through which a plurality of pixel openings are formed; and
a peripheral region adjacent to the pattern region, and
the plurality of warpage control patterns are disposed along the peripheral region.

6. The deposition mask of claim 5, wherein each of the plurality of warpage control patterns extends across the peripheral region to protrude to an inside and an outside of the peripheral region.

7. The deposition mask of claim 5, wherein
the peripheral region comprises:
a first peripheral region extending in a first direction; and
a second peripheral region extending in a second direction intersecting the first direction,
the plurality of warpage control patterns comprise:
first warpage control patterns disposed along the first peripheral region and extending in the second direction; and
second warpage control patterns disposed along the second peripheral region and extending in the first direction, and
a first warpage control pattern of the first warpage control patterns extends toward a second warpage control pattern of the second warpage control patterns, which is adjacent to the first warpage control pattern.

8. The deposition mask of claim 1, wherein
the cell opening penetrates the substrate,
the cell region is exposed through the cell opening, and
each of the plurality of warpage control patterns is partially exposed through the cell opening.

9. The deposition mask of claim 1, further comprising:
an inorganic film disposed on the substrate, wherein
the plurality of warpage control patterns are disposed on the inorganic film, and
the membrane is disposed on the plurality of warpage control patterns and the inorganic film.

10. The deposition mask of claim 1, further comprising:
an inorganic film disposed on the substrate, wherein
the plurality of warpage control patterns are disposed on the substrate,
the membrane is disposed on the plurality of warpage control patterns and the inorganic film, and
the warpage control patterns and the inorganic film have a same thickness.

11. A deposition mask comprising:
a membrane comprising a cell region disposed on a cell opening of a substrate; and
a reinforcement pattern disposed between the substrate and the membrane, extending along an edge portion of the cell region, and supporting the edge portion of the cell region to reduce warpage of the cell region.

12. The deposition mask of claim 11, wherein
the cell region comprises:
a pattern region through which a plurality of pixel openings are formed; and
a peripheral region adjacent to the pattern region, and
the reinforcement pattern has a ring shape extending along the peripheral region.

13. The deposition mask of claim 12, wherein
the cell opening penetrates the substrate,
the reinforcement pattern comprises:
an inner ring region exposed through the cell opening; and
an outer ring region disposed between the substrate and the membrane, and
the peripheral region is disposed on the inner ring region of the reinforcement pattern.

14. The deposition mask of claim 12, further comprising:
a plurality of warpage control patterns extending from the reinforcement pattern toward the pattern region.

15. The deposition mask of claim 14, wherein the reinforcement pattern and the plurality of warpage control patterns comprise a metal material.

16. The deposition mask of claim 15, wherein the plurality of warpage control patterns comprises:
first warpage control patterns including the metal material; and
second warpage control patterns formed by melting and solidifying the metal material.

17. The deposition mask of claim 11, further comprising:
an inorganic film disposed on the substrate, wherein
the reinforcement pattern is disposed on the inorganic film, and
the membrane is disposed on the reinforcement pattern and the inorganic film.

18. The deposition mask of claim 11, further comprising:
an inorganic film disposed on the substrate, wherein
the reinforcement pattern is disposed on the substrate,
the membrane is disposed on the reinforcement pattern and the inorganic film, and
the reinforcement pattern and the inorganic film have a same thickness.

19. A method of manufacturing a deposition mask, the method comprising:
forming a plurality of warpage control patterns on a substrate;
forming a membrane comprising a cell region on the plurality of warpage control patterns;
forming a cell opening exposing the cell region by partially etching the substrate;
measuring warpage of the cell region; and
controlling the warpage of the cell region based on a result of the measuring of the warpage of the cell region, wherein
the plurality of warpage control patterns are disposed along an edge portion of the cell region, and
the warpage of the cell region is controlled by melting and solidifying at least one of the plurality of warpage control patterns.

20. The method of claim 19, further comprising:
forming a reinforcement pattern having a ring shape on the substrate,
wherein the plurality of warpage control patterns extend inward from the reinforcement pattern and are formed simultaneously with the reinforcement pattern.

21. An electronic device comprising:
a display substrate; and
light-emitting layers formed on the display substrate by using a deposition mask,
wherein the deposition mask comprises:
a membrane comprising a cell region disposed on a cell opening of a mask substrate; and
a plurality of warpage control patterns disposed along an edge portion of the cell region between the mask substrate and the membrane and supporting the edge portion of the cell region in a cantilever shape to control warpage of the cell region.
